(19) United States
(12) Patent Application Publication
(10) Pub. No.: US 2026/0018209 A1
(43) Pub. Date: Jan. 15, 2026

(54) RESISTIVE MEMORY DEVICES AND METHODS OF OPERATING RESISTIVE MEMORY DEVICES

(71) Applicant: Samsung Electronics Co., Ltd., Suwon-si (KR)

(72) Inventors: Minsup Kim, Suwon-si (KR); Sunho Kwon, Suwon-si (KR); Keonhee Kim, Suwon-si (KR); Yonghwan Kim, Suwon-si (KR); Seongsu Eom, Suwon-si (KR)

(21) Appl. No.: 19/005,146

(22) Filed: Dec. 30, 2024

(30) Foreign Application Priority Data
Jul. 12, 2024 (KR) 10-2024-0092133

(51) Int. Cl. G11C 13/00

(52) U.S. Cl. CPC G11C 13/0069; G11C 13/0026; G11C 13/0028; G11C 13/003; G11C 13/0097; G11C 13/0038; G11C 2013/0078; G11C 2213/15; G11C 2213/79

(57) ABSTRACT

A resistive memory device includes a memory cell array, a write/read circuit, and a control circuit. The memory cell array includes resistive memory cells and reset transistors, each of the reset transistors is coupled to respective one of source lines, and each of the source lines is between a respective pair of adjacent word-lines. A first resistive memory cell includes a variable resistor element that is coupled to a first source line among the plurality of source lines, and a first selection transistor. The first selection transistor is coupled to a first bit-line, the variable resistor element, and a first word-line. The first bit-line is coupled to the column decoder and a first write driver of the write/read circuit. The first write driver is configured to perform a set write operation using the first selection transistor and to perform a reset write operation using the first reset transistor.

### CROSS-REFERENCE TO RELATED APPLICATION

This application claims priority under 35 U.S.C. § 119 to Korean Patent Application No. 10-2024-0092133, filed on Jul. 12, 2024, in the Korean Intellectual Property Office, the disclosure of which is incorporated by reference herein in its entirety.

Example embodiments described herein relate to memory devices, and more particularly, to resistive memory devices and/or methods of operating resistive memory devices.

### BACKGROUND

Volatile memory is a type of computer storage that only maintains its data while the device is powered. Non-volatile memory is a type of computer storage that can retrieve stored information even after having been power cycled, e.g. after loss of power. Research into next-generation memory devices that are non-volatile and do not require refresh operations is being conducted in response to demand for high capacity and low power consumption memory devices. Next-generation memory devices generally require or include the high integrity characteristics of Dynamic Random Access Memory (DRAM), the non-volatile characteristics of flash memory, and the high speed of static RAM (SRAM). Examples of next-generation memory devices include Phase change RAM (PRAM), Nano Floating Gate Memory (NFGM), Polymer RAM (PoRAM), Magnetic RAM (MRAM), Ferroelectric RAM (FeRAM), and/or Resistive RAM (RRAM).

### SUMMARY

Some example embodiments provide a resistive memory device having enhanced performance and reduced occupied area.

Some example embodiments provide a method of operating a resistive memory device, having enhanced performance and reduced occupied area.

According to some example embodiments, a resistive memory device includes a memory cell array comprising a plurality of resistive memory cells and a plurality of reset transistors, the plurality of resistive memory cells coupled to a plurality of word-lines, each of the plurality of reset transistors coupled to a respective one of a plurality of source lines that is between a respective pair of adjacent word-lines among the plurality of word-lines; and a write/read circuit connected to the memory cell array through a row decoder and through a column decoder, the write/read circuit configured to write a write data in a target page of the memory cell array. A first resistive memory cell of the target page among the plurality of resistive memory cells includes a variable resistor element coupled to a first source line among the plurality of source lines; and a first selection transistor coupled to a first bit-line, the variable resistor element, and a first word-line among the plurality of word-lines. The first bit-line is coupled to the column decoder and a first write driver of the write/read circuit. A first reset transistor among the plurality of reset transistors is connected to the first source line, a reset word-line, and a reset bit-line. The first write driver is configured to perform a set write operation using the first selection transistor and perform a reset write operation using the first reset transistor.

According to some example embodiments, there is provided a method of operating a resistive memory device including a memory cell array that comprises a plurality of resistive memory cells and a plurality of reset transistors, the plurality of resistive memory cells coupled to a plurality of word-lines, each of the plurality of reset transistors coupled to respective one of a plurality of source lines that is between a respective pair of adjacent word-lines among the plurality of word-lines. The method includes receiving a write command from an external memory controller; receiving an address and a data from the external memory controller; performing a reset write operation on a target page of the memory cell array by applying a power supply voltage to a first word-line among the plurality of word-lines, by applying a ground voltage to a plurality of bit-lines, and by applying the power supply voltage to a first reset word-line and a first reset bit-line that are coupled to a gate and a drain, respectively, of a first reset transistor among the plurality of reset transistors, where each of the resistive memory cells of the target page includes a variable resistor element that is coupled to a first source line among the plurality of source lines, and a selection transistor that is coupled to the first word-line and a first bit line among a plurality of bit-lines coupled to a column decoder and a write driver circuit, where the first reset transistor is coupled to the first source line; and performing a set write operation on a portion of the target page corresponding to bits having a logic high level, among the data, by applying the power supply voltage to the first word-line, by applying the power supply voltage to a subset of the plurality of bit-lines based on the data, and by applying the ground voltage to the first source line.

According to some example embodiments, a resistive memory device includes a memory cell array comprising a plurality of resistive memory cells and a plurality of reset transistors, the plurality of resistive memory cells coupled to a plurality of word-lines, each of the plurality of reset transistors coupled to respective one of a plurality of source lines that is between a respective pair of adjacent word-lines among the plurality of word-lines; a write/read circuit connected to the memory cell array through a row decoder and through a column decoder, the write/read circuit configured to write a write data in a target page of the memory cell array; and a control circuit configured to control the row decoder, the column decoder, and the write/read circuit based on a command and an address. A first resistive memory cell of the target page among the plurality of resistive memory cells comprises a variable resistor element coupled to a first source line among the plurality of source lines; and a first selection transistor coupled to a first bit-line, the variable resistor element, and a first word-line among the plurality of word-lines. The first bit-line is coupled to the column decoder and a first write driver of the write/read circuit, and a first reset transistor among the plurality of reset transistors is connected to the first source line, a reset word-line, and a reset bit-line. The first write driver is configured to perform a set write operation using the first selection transistor and perform a reset write operation using the first reset transistor. The first selection transistor and the first reset transistor are configured to operate in a saturation region during the set write operation and the reset write operation, respectively.

Accordingly, the resistive memory device may include a plurality of resistive memory cells coupled to a plurality of word-lines and a plurality of reset transistors, each of the plurality of resistive memory cells includes a variable resistor element coupled to respective one of a plurality of source lines, each of the plurality source lines is connected to respective one of the reset transistors, and each of the plurality source lines is shared by two adjacent word-lines. The resistive memory device is configured to perform a set write operating using a selection transistor in the resistive memory cell and perform a reset write operating using a reset transistor that operates in a saturation region. Because resistive memory cells coupled to the two adjacent word-lines commonly use one reset transistor, occupied area may be reduced. In addition, because each of the selection transistor and the reset transistor operates in the saturation region, a set current having sufficient magnitude is generated when the power supply voltage is applied to the bit-line. Accordingly, resistive memory device may reduce power consumption and enhance performance by increasing uniformity characteristics of the resistive memory cells.

### BRIEF DESCRIPTION OF THE DRAWINGS

The above and other features of the present disclosure will be more clearly understood by describing in detail example embodiments thereof with reference to the accompanying drawings.

FIG. 1 is a block diagram illustrating a memory system according to some example embodiments.

FIG. 2 is a block diagram illustrating an example of the memory controller in FIG. 1 according to some example embodiments.

FIG. 3 is a block diagram illustrating an example of the resistive memory device in FIG. 1 according to some example embodiments.

FIG. 4 is a circuit diagram illustrating an example of the memory cell array in FIG. 3 according to some example embodiments.

FIG. 5 is a circuit diagram of an example of one of the resistive memory cells in FIG. 4 according to example embodiments.

FIG. 6 is a diagram illustrating an example of the memory cell array in FIG. 3 according to example embodiments.

FIG. 7A is a graph showing set write operation and reset write operation for the variable resistor element of the resistive memory cell of FIG. 5.

FIG. 7B is a graph showing a distribution of resistive memory cells according to resistance when the resistive memory cell of FIG. 5 is a single level cell.

FIG. 8 is a graph showing a relationship between a drain-source voltage and a drain-source current of a selection transistor in the resistive memory cell of FIG. 5 according to example embodiments.

FIG. 9 is a block diagram illustrating an example of the control circuit in the resistive memory device of FIG. 3 according to some example embodiments.

FIG. 10 illustrates a portion of the resistive memory device of FIG. 3 according to example embodiments.

FIG. 11 illustrates an example of a first row of resistive memory cell, a first reset transistor and a first write driver in the resistive memory device of FIG. 10 according to example embodiments.

FIG. 12 illustrates resistive memory cell, a first reset transistor and a first write driver in the resistive memory device in FIG. 11 in a stand-by state according to example embodiments.

FIG. 13 illustrates resistive memory cell, a first reset transistor and a first write driver in the resistive memory device in FIG. 11 during a set write operation according to example embodiments.

FIG. 14 illustrates resistive memory cell, a first reset transistor and a first write driver in the resistive memory device in FIG. 11 during a reset write operation according to example embodiments.

FIG. 15 illustrates resistive memory cell, a first reset transistor and a first write driver in the resistive memory device in FIG. 11 during a set write operation according to example embodiments.

FIG. 16 illustrates a portion of a resistive memory device according to example embodiments.

FIG. 17 illustrates an example of a first row of resistive memory cell, a first reset transistor, a first column write driver and a first row write driver in the resistive memory device of FIG. 16 according to example embodiments.

FIG. 18 illustrates resistive memory cell, a first reset transistor, a first column write driver and a first row write driver in the resistive memory device in FIG. 17 in a stand-by state according to example embodiments.

FIG. 19 illustrates resistive memory cell, a first reset transistor, a first column write driver and a first row write driver in the resistive memory device in FIG. 17 during a set write operation according to example embodiments.

FIG. 20 illustrates resistive memory cell, a first reset transistor, a first column write driver and a first row write driver in the resistive memory device in FIG. 17 during a reset write operation according to example embodiments.

FIG. 21 illustrates a circuit diagram illustrating components associated with performing a read operation of a resistive memory device according to example embodiments.

FIG. 22 is a flow chart illustrating a method of operating a resistive memory device according to example embodiments.

FIG. 23 is a flow chart illustrating a method of operating a resistive memory device according to example embodiments.

FIG. 24 illustrates a memory device having a cell over peripheral (COP) structure according to example embodiments.

FIG. 25 is a block diagram illustrating a mobile system according to some example embodiments.

### DETAILED DESCRIPTION

Example embodiments of the present disclosure will be described more fully hereinafter with reference to the accompanying drawings. Like reference numerals may refer to like elements throughout this application. The terms “first,” “second,” etc., may be used herein merely to distinguish one component, element, etc., from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or elements are referred to herein as “directly” on or “directly connected,” no intervening components or elements are present.

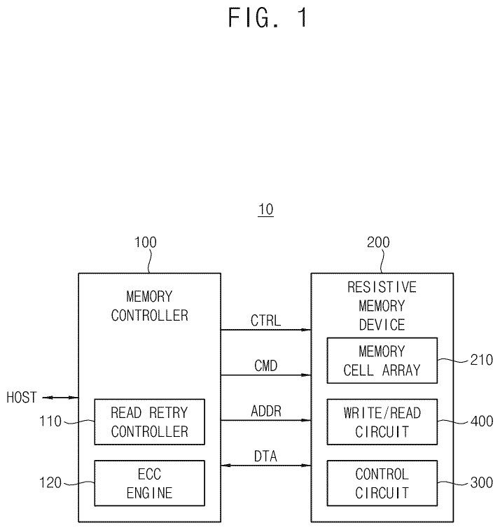

FIG. 1 is a block diagram illustrating a memory system according to some example embodiments.

In example embodiments, a memory device may be referred to as a resistive type memory device because the memory device includes resistive type memory cells. Alternatively or additionally, the memory device may include various types of memory cells. For example, the memory device may include a heterogeneous collection of memory cells. Since the memory cells may be disposed at cross-points of multiple first signal lines, multiple second signal lines and multiple third signal lines, the memory device may be referred to as a cross-point memory device.

Referring to FIG. 1, a memory system 10 may include a memory controller 100 and a resistive memory device 200. The resistive memory device 200 may include a memory cell array 210, a control circuit 300, and a write/read circuit 400. The memory cell array 210 may include a plurality of resistive (type) memory cells.

In response to a write/read request from a host, the memory controller 100 may read data stored in the resistive memory device 200 and/or may control the resistive memory device 200 to write data to the resistive memory device 200. In some example embodiments, the memory controller 100 may provide an address (signal) ADDR, a command (signal) CMD, and a control signal CTRL to the resistive memory device 200 to control a program (or write) operation and/or a read operation with respect to the resistive memory device 200.

In addition, write-target data DTA and read data DTA may be exchanged between the memory controller 100 and the resistive memory device 200. For example, the write-target data DTA may be written to the resistive memory device 200 in response to a write command and the read data DTA may be read from the resistive memory device 200 in response to a read command.

In addition, the memory controller 100 may include a read-retry controller 110 (e.g., a control circuit) and/or an error correction code (ECC) engine 120 (e.g., an ECC circuit). The ECC engine 120 may perform error detection and correction on data that is provided from the resistive memory device 200. For example, the ECC engine 120 may detect whether the data has an error and potentially correct the error.

Although not illustrated, the memory controller 100 may include a random access memory (RAM), a processing unit, a host interface, and/or a memory interface. The RAM may be used as an operation memory of the processing unit. The processing unit may control operations of the memory controller 100. The host interface may include a protocol for exchanging data between the host and the memory controller 100. The memory interface may include a protocol for exchanging data between the memory controller 100 and the resistive memory device 200.

The memory cell array 210 may include a plurality of resistive memory cells (not shown) that are disposed respectively in regions where first signal lines, second signal lines and third signal lines cross. In addition, each of the resistive memory cells may be a single level cell (SLC) that stores one bit data, or may be a multilevel cell (MLC) that stores at least two-bit data.

Alternatively, the memory cell array 210 may include both the SLCs and the MLCs. When one bit data is written to one memory cell, the memory cells may have two resistance level distributions according to the written data. Alternatively, when two-bit data is written to one memory cell, the memory cells may have four resistance level distributions according to the written data. In another embodiment, when a memory cell is a triple level cell (TLC) that stores three-bit data, the memory cells may have eight resistance level distributions according to the written data. However, embodiments of the inventive concepts are not limited thereto. For example, each of the memory cells may store at least four-bit data in another embodiment.

In some example embodiments, the memory cell array 210 may include memory cells with a two-dimensional horizontal structure. Alternatively or additionally, the memory cell array 210 may include memory cells with a three-dimensional vertical structure.

The memory cell array 210 may include resistive-type (resistive) memory cells that include a variable resistor element (not shown). For one example, when resistance of the variable resistor element that is formed of a phase change material (e.g., Ge—Sb—Te) is changed according to a temperature, a resistive memory device is a phase change RAM (PRAM). As another example, when the variable resistor element is formed of a complex metal oxide including an upper electrode, a lower electrode, and a transition metal oxide therebetween, the resistive memory device is a resistive RAM (RRAM). As another example, when the variable resistor element is formed of an upper electrode of a magnetic material, a lower electrode of the magnetic material, and a dielectric therebetween, the resistive memory device is a magnetic RAM (MRAM).

The write/read circuit (or read/write circuit) 400 may perform a write operation and a read operation on the memory cells. In some example embodiments, the write/read circuit 400 may be connected to the memory cells through a plurality of bit-lines and a plurality of source lines, and may include write drivers (e.g., driving circuits) that write data to the memory cells, and sense amplifiers that sense resistive components of the memory cells.

In some example embodiments, the control circuit 300 may control operations of the resistive memory device 200, and may control the write/read circuit 400 so as to perform a memory operation such as a write operation or a read operation. For the write and read operations of the resistive memory device 200, the control circuit 300 may provide pulse signals such as a write pulse or a read pulse to the write/read circuit 400. For example, the write/read circuit 400 may provide a write current (or a write voltage) in response to the write pulse to the memory cell array 210 and provide a read current (or a read voltage) in response to the read pulse to the memory cell array 210. The read current and the write current (or the read voltage and the write voltage) may be the same as, or different from, each other.

In the write operation on the resistive memory device 200, a resistance value of a variable resistor of a memory cell of the memory cell array 210 may be increased or decreased, depending on write data associated with the write operation. For example, each of the memory cells of the memory cell array 210 may have a resistance value according to data that is currently stored therein, and the resistance value may be increased or decreased, depending on data to be written to each of the memory cells.

In some example embodiments, the write operation is divided into (i.e., may include) a reset write operation and a set write operation. In a set state, a resistive memory cell may have a relatively low resistance value, and in a reset state, the resistive memory cell may have a relatively high resistance value. The reset write operation may involve performing a write operation so as to increase a resistance value of a variable resistor of the resistive memory cell, and the set write operation may involve performing a write operation so as to decrease the resistance value of the variable resistor of the resistive memory cell.

In some example embodiments, when a detected error of data read by the resistive memory device 200 is not correctable, the memory controller 100 may control the resistive memory device 200 to operate in a read-retry mode to perform a read-retry operation. For example, the ECC engine 120 may determine whether the data read has an error and whether that error is correctable. During the read-retry operation, the memory device 200 may read (or re-read) data while the memory device 200 changes a reference (e.g., a read reference) for determining data “0” and data “1”, analyzes a valley in a resistance level distribution of memory cells by performing a data determination operation on the read data, and based on the analysis result, perform a recovery algorithm of selecting a read reference so as to minimize or reduce error occurrence of the data.

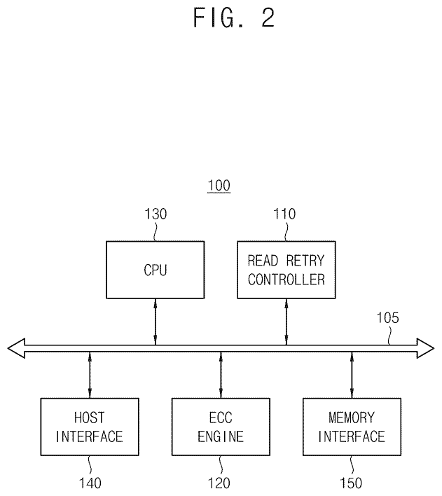

FIG. 2 is a block diagram illustrating an example of the memory controller in FIG. 1 according to some example embodiments.

Referring to FIG. 2, the memory controller 100 may include the read-retry controller 110, the ECC engine 120, a central processing unit (CPU) 130, a host interface 140, and a memory interface 150. The read-retry controller 110, the ECC engine 120, the CPU 130, the host interface 140, and the memory interface 150 may communicate with one another through a system bus 105.

The CPU 130 may control operations of the memory controller 100. For example, the CPU 130 may control various function blocks related to a memory operation on the resistive memory device 200. The host interface 140 may interface with the host. Examples of this interfacing may include receiving a request for the memory operation from the host. For example, the host interface 140 may receive, from the host, requests for reading and/or writing data, and in response to the requests, the host interface 140 may generate internal signals for the memory operation on the resistive memory device 200.

In some example embodiments, the ECC engine 120 may perform an ECC encoding process on write data and an ECC decoding process on read data. For example, the ECC engine 120 may perform an error detection operation on data that is read from the resistive memory device 200, and may perform an error correction operation on the read data when a result of the error detection operation indicates an error is present. The read-retry controller 110 may provide various types of information for controlling an operation of the resistive memory device 200 during the read-retry mode, as previously described. The memory interface 150 may interface with the resistive memory device 200 to exchange various signals (e.g., command, address, mode signals, reference information, data, etc.) between the memory controller 100 and the resistive memory device 200.

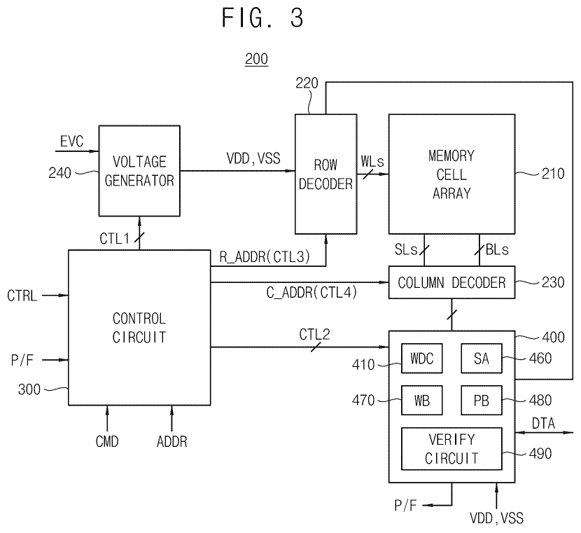

FIG. 3 is a block diagram illustrating an example of the resistive memory device in FIG. 1 according to some example embodiments.

Referring to FIG. 3, the resistive memory device 200 may include the memory cell array 210, the control circuit 300 and the write/read circuit 400. The resistive memory device 200 may further include a row decoder 220, a column decoder 230 and a voltage generator 240. The write/read circuit 400 may include a write driver circuit WDC 410, a read circuit SA 460, a write buffer WB 470, a page buffer PB 480 and a verify circuit 490. The read circuit 460 may be referred to as a sense amplifier.

Resistive memory cells that are arranged in the memory cell array 210 are connected to word-lines WLs, bit-lines BLs and source lines SLs. Since various voltage signals or current signals are provided via the bit-lines BLs, the source lines SLs and the word-lines WLs, data may be written to or read from selected memory cells, and writing data to or reading data from residual unselected memory cells may be prevented.

The address (or, access address) ADDR accompanied with the command CMD for indicating an access-target memory cell may be received by the control circuit 300. In an embodiment, the address ADDR may include a row address R_ADDR for selecting word-lines WLs of the memory cell array 210, and a column address C_ADDR for selecting bit-lines BLs of the memory cell array 210. The row decoder 220 may perform a word-line selecting operation in response to the row address R_ADDR, and the column decoder 230 may perform a bit-line selecting operation in response to the column address C_ADDR.

The write/read circuit 400 may be connected to the bit-lines BLs and thus may write data to a memory cell or may read data from the resistive memory cells. The write/read circuit 400 may be connected to the row decoder 220 and the column decoder 230.

For example, a power supply voltage (e.g., a first driving voltage) VDD and a ground voltage (e.g., a second driving voltage) may be provided from the voltage generator 240 to a selected memory cell, inhibit voltages may be provided from the voltage generator 240 to unselected word-lines and unselected bit-lines, and in a read operation, a read voltage may be provided from the voltage generator 240 to the selected memory cell.

The write/read circuit 400 may provide a write voltage or a write current according to data to the memory cell array 210 via the column decoder 230. In addition, in order to determine the data in the read operation, the write/read circuit 400 may include a comparator that is connected to a node (e.g., a data sensing node) of a bit-line BL, and may read a data value by performing a comparison operation on a sensing voltage or a sensing current of the sensing node.

In addition, the write/read circuit 400 may provide the control circuit 300 with a pass/fail signal P/F according to a read result with respect to the read data. The control circuit 300 may refer to the pass/fail signal P/F and thus control write and read operations of the memory cell array 210.

In example embodiments, the control circuit 300 may generates a plurality of control signals CTL1, CTL2, CTL3 and CTL4 based on the command CMD, the address ADDR, the control signal CTRL and the pass/fail signal P/F. In an embodiment, the control circuit 300 may provide a first control signal CTL1 to the voltage generator 240, provide a second control signal CTL2 to the write/read circuit 400, provide a third control signal CTL3 to the row decoder 220 and provide a fourth control signal CTL4 to the column decoder 230.

The voltage generator 240 may generate the power supply voltage VDD and the ground voltage VSS based on the external voltage EVC and may provide the power supply voltage VDD and the ground voltage VSS to the row decoder 220 and the write/read circuit 400.

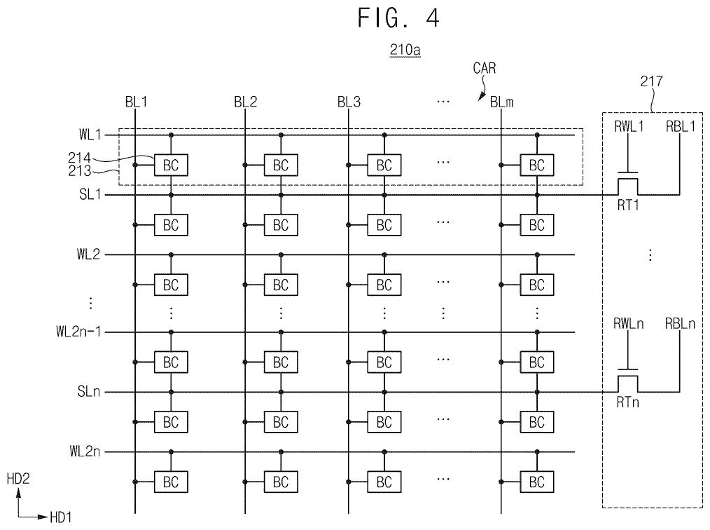

FIG. 4 is a circuit diagram illustrating an example of the memory cell array in FIG. 3 according to some example embodiments.

Referring to FIG. 4, a memory cell array 210a may include a cell region CAR and a reset transistor region 217.

The cell region CAR may include a plurality of word-lines WL1, WL2, . . . , WL2n−1 and WL2n, a plurality of bit-lines BL1, BL2, BL3, . . . , BLm, a plurality of source lines SL1, SL2, SL3, . . . , SLn and a plurality of resistive memory cells BC 214. Here, n may be a natural number greater than 1 and m may a natural number greater than 3. The plurality of resistive memory cells 214 coupled to a same word-line may be defined as a page 213.

The plurality of word-lines WL1, WL2, . . . , WL2n−1 and WL2n may extend in a first horizontal direction HD1, the plurality of source lines SL1, SL2, SL3, . . . , SLn may extend in the first horizontal direction HD1 and the plurality of bit-lines BL1, BL2, BL3, . . . , BLm may extend in a second horizontal direction HD2 crossing the first horizontal direction HD1.

Each of the plurality of source lines SL1, SL2, SL3, . . . , SLn may be disposed between two adjacent word-lines among the plurality of word-lines WL1, WL2, . . . , WL2n−1 and WL2n. For example, the source line SL1 may be disposed between the word-lines WL1 and WL2 and the source line SLn may be disposed between the word-lines WL2n−1 and WL2n. A row of resistive memory cells coupled to each of the word-lines WL1 and WL2 may be commonly coupled to the source line SL1.

The reset transistor region 217 may include a plurality of reset transistors RT1, . . . , RTn, each of which is coupled to respective one of the plurality of source lines SL1, SL2, SL3, . . . , SLn, a plurality of reset word-lines RWL1, . . . , RWLn and a plurality of reset bit-lines RWL1, . . . , RWLn. Each of the plurality of reset word-lines RWL1, . . . , RWLn and each of the plurality of reset bit-lines RBL1, . . . , RBLn may be connected to respective one of the plurality of reset transistors RT1, . . . , RTn.

Each of the plurality of resistive memory cells 214 may be referred to as a bit-cell. Each of the plurality of resistive memory cells 214 may include a variable resistor element coupled to respective one of the plurality of source lines SL1, SL2, SL3, . . . , SLn and a selection transistor coupled to respective one of the plurality of word-lines WL1, WL2, . . . , WL2n−1 and WL2n and respective one of the plurality of bit-lines BL1, BL2, BL3, . . . , BLm. The variable resistor element may be also referred to as a variable resistor.

A resistance value of the variable resistor element may be changed to one of multiple resistive states. For example, the resistance value may change in response to an electric pulse being applied to the corresponding variable resistor element. In an embodiment, the variable resistor element may include a phase-change material having a crystal state that changes according to a current. The phase-change material may include materials, such as GaSb, InSb, InSe, or Sb₂Te₃ obtained by compounding two elements, GeSbTe, GaSeTe, InSbTe, SnSb₂Te₄, or InSbGe obtained by compounding three elements, or AgInSbTe, (GeSn)SbTe, GeSb(SeTe) obtained by compounding four elements.

In some example embodiments, the phase-change material has an amorphous state that is relatively high-resistive, and a crystal state that is relatively low-resistive. A phase of the phase-change material may be changed by Joule heat that is generated by the current. Using changes of the phase, data may be written to the corresponding cell.

In another embodiment, the variable resistor element does not include the phase-change material, but includes perovskite compounds, transition metal oxide, magnetic materials, ferromagnetic materials, or antiferromagnetic materials, for example.

The write driver circuit 410 in FIG. 3 may perform a set write operation using a selection transistor in each of the resistive memory cells 214 and perform a reset write operation using each of the plurality of reset transistors RT1, . . . , RTn.

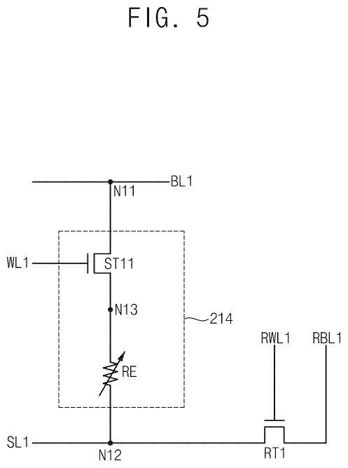

FIG. 5 is a circuit diagram of an example of one of the resistive memory cells in FIG. 4 according to example embodiments.

Referring to FIG. 5, a resistive memory cell 214 may be coupled to a first word-line WL1, a first bit-line BL1 and a first source line SL1, the first source line SL1 may be coupled to a first reset transistor RT1 and the first reset transistor RT1 may be coupled to a first reset word-line RWL1 and a first reset bit-line RBL1.

The resistive memory cell 214 may include a selection transistor ST11 and a variable resistor element RE. The selection transistor ST11 may be connected to the first bit-line BL1 at a first node N11 and may be connected to the variable resistor element RE at a third node N13. The variable resistor element RE may be connected to the first source line SL1 at a second node N12. The selection transistor ST11 may include an n-channel metal-oxide semiconductor (NMOS) transistor that has a drain coupled to the first bit-line BL1, a gate coupled to the first word-line WL1 and a source coupled to the variable resistor element RE.

The first reset transistor RT1 may include an NMOS transistor that has a drain coupled to the first reset bit-line RBL1, a gate coupled to the first reset word-line RWL1 and a source coupled to the first source line SL1.

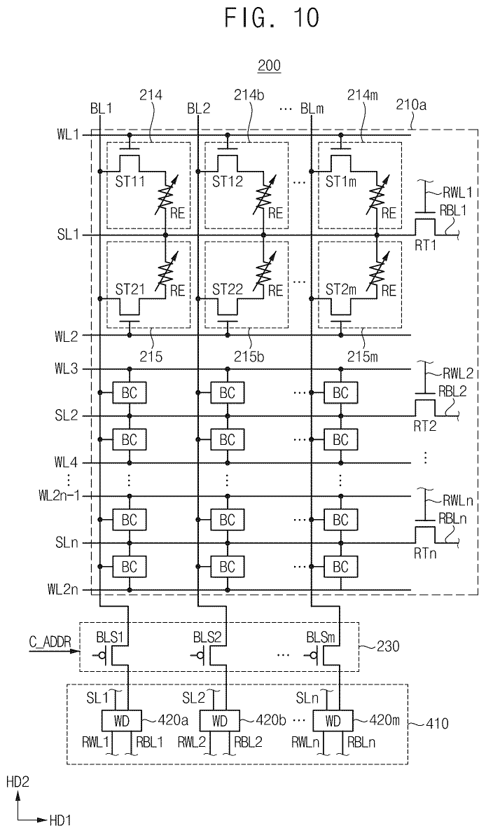

A first write driver 420a in FIG. 10 may perform a set write operation using the selection transistor ST11 and perform a reset write operation using the first reset transistor RT1.

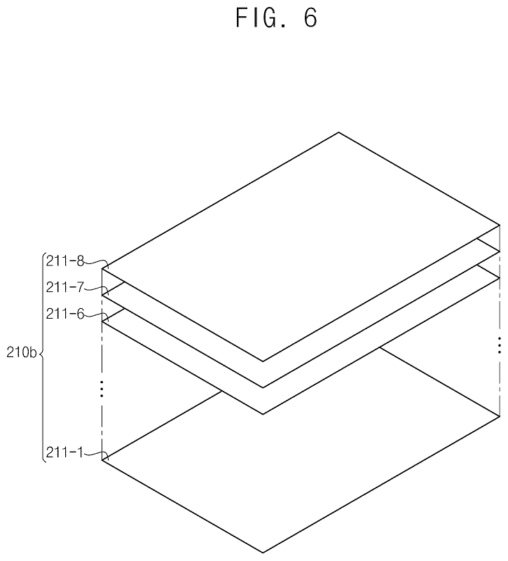

FIG. 6 is a diagram illustrating an example of the memory cell array in FIG. 3 according to example embodiments. It will be understood that spatially relative terms such as ‘above,’ ‘upper,’ ‘below,’ ‘lower,’ and the like may be denoted by reference numerals and refer to the drawings, except where otherwise indicated. It will be understood that such spatially relative terms are intended to encompass different orientations of the device in use or operation in addition to the orientation depicted in the figures.

Referring to FIG. 6, a memory cell array 210b is implemented with a three-dimensional stacked structure. The example three-dimensional stacked structure includes multiple, vertically stacked, memory cell layers 211_1, . . . , 211_6, 211_7 and 211_8. However, those of ordinary skill in the art will understand that the number of vertically stacked memory cell layers is an arbitrary one.

When the memory cell array 210b has a three-dimensional laminated structure, each of the memory cell layers 211_1, . . . , 211_6, 211_7 and 211_8 has the cross point structure illustrated in FIG. 4.

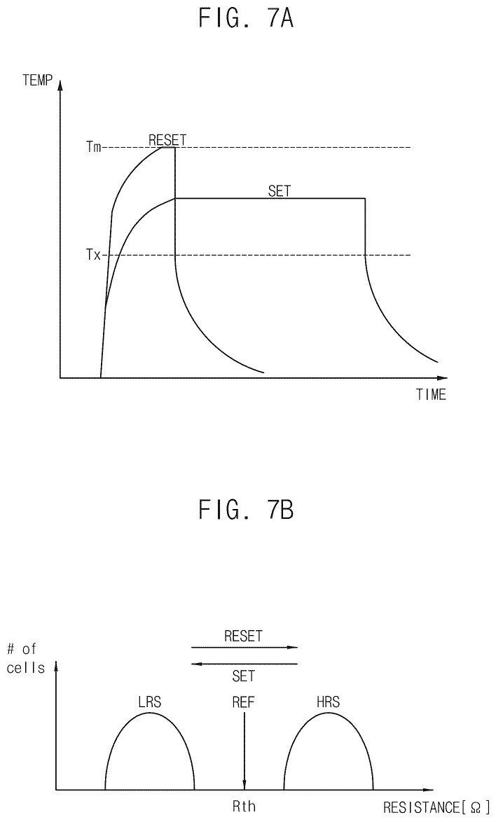

FIG. 7A is a graph showing set write operation and reset write operation for the variable resistor element of the resistive memory cell of FIG. 5 and FIG. 7B is a graph showing a distribution of resistive memory cells according to resistance when the resistive memory cell of FIG. 5 is a single level cell.

Referring to FIGS. 5 and 7A together, a horizontal axis of FIG. 7A represents time and a vertical axis of FIG. 7A represents temperature TEMP. When a phase change material constituting the variable resistor element RE is heated to a temperature between a crystallization temperature Tx and a melting point Tm for a certain period of time and then gradually cooled, the phase change material is in a crystalline state. This crystalline state is referred to as a ‘set state’ in which data ‘1’ is stored. On the other hand, when the phase change material is quenched after being heated to a temperature above the melting point Tm, the phase change material is in an amorphous state. This amorphous state is referred to as a ‘reset state’ in which data ‘0’ is stored. Therefore, a current may be supplied to the variable resistor element RE to store data, and the resistance value of the variable resistor element RE may be measured to read data.

Referring to FIGS. 5 and 7B together, a horizontal axis of FIG. 7B represents resistance and a vertical axis of FIG. 7B represents the number of resistive memory cells. When the resistive memory cell (for example, the resistive memory cell 124) is a single level cell, the resistive memory cell may be in one of a low resistance state LRS, that is, a set state SET, and a high resistance state HRS, that is, a reset state RESET. Accordingly, the operation of switching the resistive memory cell 124 from the low resistance state LRS to the high resistance state HRS may be referred to as a reset operation or a reset write operation. In addition, the operation of switching the resistive memory cell 124 from the high resistance state HRS to the low resistance state LRS may be referred to as a set operation or a set write operation.

A resistance between the distribution of the low resistance state LRS and the distribution of the high resistance state HRS may be set to be a threshold resistance Rth. In a read operation performed on the resistive memory cells, when a read result is equal to or greater than the threshold resistance Rth, the read result may be determined to be high resistance state HRS, and when the read result is less than the threshold resistance Rth, the read result may be determined to be the low resistance state LRS. In an embodiment, information on read reference REF corresponding to the threshold resistance Rth may be received from the memory controller 100.

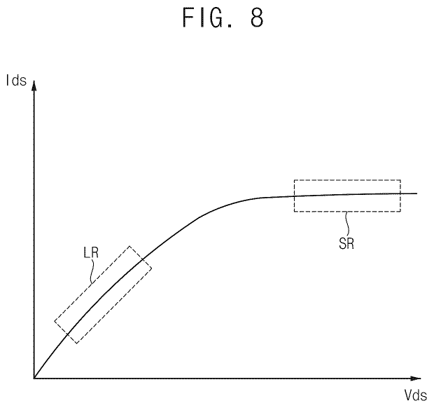

FIG. 8 is a graph showing a relationship between a drain-source voltage and a drain-source current of a selection transistor in the resistive memory cell of FIG. 5 according to example embodiments.

Referring to FIG. 8, as a drain-source voltage Vds of the first selection transistor ST11 increases, a drain-source current Ids of the selection transistor ST11 linearly increases and is maintained at a constant value. When the selection transistor ST11 operates in a linear region LR, the drain-source current Ids of the selection transistor ST11 linearly increases in response to the drain-source voltage Vds of the selection transistor ST11 and when selection transistor ST11 operates in a saturation region SR, the drain-source current Ids of the selection transistor ST11 is maintained at a substantially constant value even though the drain-source voltage Vds of the selection transistor ST11 increases.

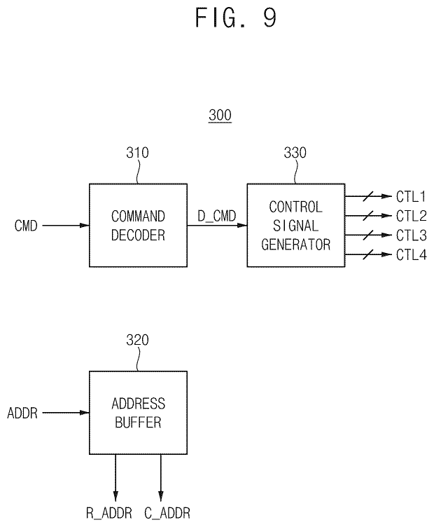

FIG. 9 is a block diagram illustrating an example of the control circuit in the resistive memory device of FIG. 3 according to some example embodiments.

Referring to FIG. 9, the control circuit 300 may include a command decoder 310, an address buffer 320 and a control signal generator 330.

The command decoder 310 may generate a decoded command D_CMD by decoding the command CMD, and may provide the decoded command D_CMD to the control signal generator 330.

The address buffer 320 may receive the address ADDR, may provide the row address R_ADDR to the row decoder 220 and may provide the column address C_ADDR to the column decoder 230.

The control signal generator 330 may receive the decoded command D_CMD and may generate the first through fourth control signals CTL1˜CTL4 based on an operation designated by the decoded command D_CMD.

The control signal generator 340 may provide the first control signal CTL1 to the voltage generator 240, may provide the second control signal CTL2 to the write/read circuit 400, may provide the third control signal CTL3 to the row decoder 220 and may provide the fourth control signal CTL4 to the column decoder 230.

FIG. 10 illustrates a portion of the resistive memory device of FIG. 3 according to example embodiments.

Referring to FIG. 10, the resistive memory device 200 may include the memory cell array 210a, the row decoder 220 (not shown), the column decoder 230 and a write driver circuit 410.

As described with reference to FIG. 4, the memory cell array 210a includes the plurality of word-lines WL1, WL2, WL3, WL4, . . . , WL2n−1 and WL2n, the plurality of bit-lines BL1, BL2, . . . , BLm, the plurality of source lines SL1, SL2, . . . , SLn, the plurality of resistive memory cells and the plurality of reset transistors RT1, RT2, . . . , RTn.

Each of the plurality of source lines SL1, SL2, . . . , SLn may be disposed between two adjacent word-lines among the plurality of word-lines WL1, WL2, WL3, WL4, . . . , WL2n−1 and WL2n. For example, the source line SL1 may be disposed between the word-lines WL1 and WL2, the source line SL2 may be disposed between the word-lines WL3 and WL4 and the source line SLn may be disposed between the word-lines WL2n−1 and WL2n. A row of resistive memory cells coupled to each of the word-lines WL1 and WL2 may be commonly coupled to the source line SL1. Each of the plurality of reset word-lines RWL1, RWL2, . . . , RWLn and each of the plurality of reset bit-lines RBL1, RBL2, . . . , RBLn may be connected to respective one of the plurality of reset transistors RT1, RT2, . . . , RTn.

Each of a first row of resistive memory cells 214, 214b, . . . , 214m may be connected to the first word-line WL1, the first source line SL1 and respective one of the plurality of bit-lines BL1, BL2, . . . , BLm. The first row of resistive memory cells 214, 214b, . . . , 214m may include respective one of selection transistors ST11, ST12, . . . , ST1m and the variable resistor element RE. The variable resistor element RE in each of the first row of resistive memory cells 214, 214b, . . . , 214m may be commonly coupled to the first source line SL1 and may be coupled to the first reset transistor RT1 through the first source line SL1.

Each of a second row of resistive memory cells 215, 215b, . . . , 215m may be connected to the second word-line WL2, the first source line SL1 and respective one of the plurality of bit-lines BL1, BL2, . . . , BLm. The second row of resistive memory cells 215, 215b, . . . , 215m may include respective one of selection transistors ST21, ST22, . . . , ST2m and the variable resistor element RE. The variable resistor element RE in each of the second row of resistive memory cells 215, 215b, . . . , 215m may be commonly coupled to the first source line SL1 and may be coupled to the first reset transistor RT1 through the first source line SL1.

That is, the first row of resistive memory cells 214, 214b, . . . , 214m and the second row of resistive memory cells 215, 215b, . . . , 215m may be coupled to the first reset transistor RT1 through the first source line SL1.

The column decoder 230 may include a plurality of bit-line switches BLS1, BLS2, . . . , BLSm. The write driver circuit 410 may include a plurality of write drivers WD 420a, 420b, . . . , 420m. Each of the plurality of bit-line switches BLS1, BLS2, . . . , BLSm may be referred to as a bit-line selection switch.

Each of the plurality of bit-line switches BLS1, BLS2, . . . , BLSm may be connected to respective one of the plurality of bit-lines BL1, BL2, . . . , BLm, and may connect a target write driver among the plurality of write drivers 420a, 420b, 420c, . . . , 420m to a target memory cell, based on the column address C_ADDR.

Each of the plurality of write drivers 420a, 420b, 420c, . . . , 420m may be connected to respective one of the plurality of bit-lines BL1, BL2, . . . , BLm, respective one of the plurality of source lines SL1, SL2, . . . , SLn, respective one of the plurality of reset word-lines RWL1, RWL2, . . . , RWLn and respective one of the plurality of reset bit-lines RBL1, RBL2, . . . , RBLn.

In a write operation, each of the plurality of write drivers 420a, 420b, 420c, . . . , 420m may drive a bit-line of the target memory cell with one of the power supply voltage VDD and the ground voltage VSS and may drive a source-line of the target memory cell with the ground voltage VSS, based on the data DTA, the power supply voltage VDD and the ground voltage VSS.

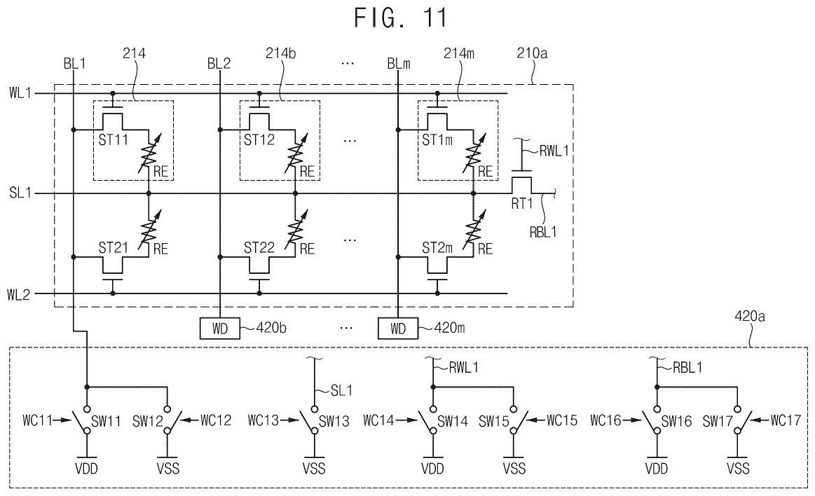

FIG. 11 illustrates an example of a first row of resistive memory cell, a first reset transistor and a first write driver in the resistive memory device of FIG. 10 according to example embodiments.

In FIG. 11, the bit-line switch BLS1 is turned-on, the bit-line BL1 is connected to the first write driver 420a and the first word-line WL1 is selected as a target word-line (e.g., a target page). In FIG. 11, a second row of resistive memory cells are illustrated together for convenience of explanation.

As described with reference to FIG. 10, the first row of resistive memory cells 214, 214b, . . . , 214m may be connected to the first word-line WL1, the first source line SL1 and respective one of the plurality of bit-lines BL1, BL2, . . . , BLm. The first row of resistive memory cells 214, 214b, . . . , 214m may include respective one of selection transistors ST11, ST12, . . . , ST1m and the variable resistor element RE. The variable resistor element RE in each of the first row of resistive memory cells 214, 214b, . . . , 214m may be commonly coupled to the first source line SL1 and may be coupled to the first reset transistor RT1 through the first source line SL1.

The first write driver 420a may include a first switch SW11, a second switch SW12, a third switch SW13, a fourth switch SW14, a fifth switch SW15, a sixth switch SW16 and a seventh switch SW17.

The first switch SW11 may selectively provide the power supply voltage VDD to the first bit-line BL1 based on a first write control signal WC11, and the second switch SW12 may selectively provide the ground voltage VSS to the first bit-line BL1 based on a second write control signal WC12. The third switch SW13 may provide the ground voltage VSS to the first source line SL1 based on a third write control signal WC13.

The fourth switch SW14 may selectively provide the power supply voltage VDD to the first reset word-line RWL1 based on a fourth write control signal WC14, and the fifth switch SW15 may selectively provide the ground voltage VSS to the first reset word-line RWL1 based on a fifth write control signal WC15.

The sixth switch SW16 may selectively provide the power supply voltage VDD to the first reset bit-line RBL1 based on a sixth write control signal WC16, and the seventh switch SW17 may selectively provide the ground voltage VSS to the first reset bit-line RBL1 based on a seventh write control signal WC17.

Although a configuration of the first write driver 420a is illustrated in FIG. 11, each of the write drivers 420b, 420c, . . . , 420m may have a substantially same configuration of the configuration of the first write driver 420a.

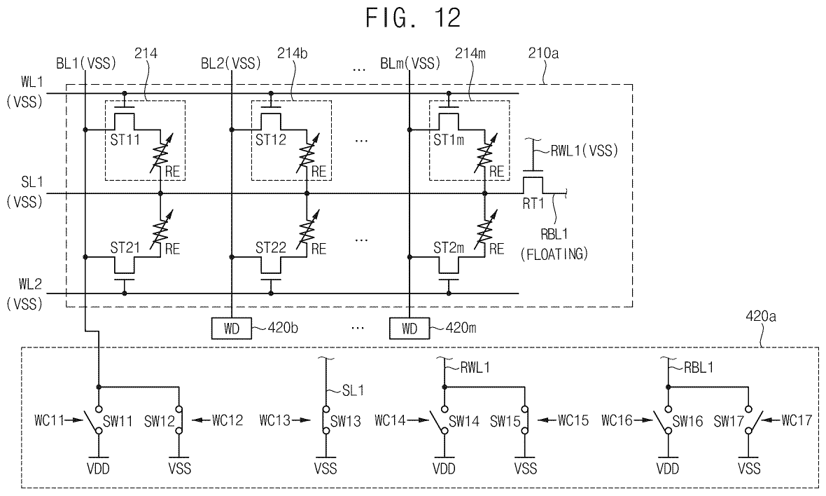

FIG. 12 illustrates resistive memory cell, a first reset transistor and a first write driver in the resistive memory device in FIG. 11 in a stand-by state according to example embodiments.

During a stand-by state, the control circuit 300 in FIG. 3 may provide the ground voltage VSS to the first bit-line BL1 by opening the first switch SW11 using the first write control WC11 and by closing the second switch SW12 using the second write control WC12 and may provide the ground voltage VSS to the first source line SL1 by closing the third switch SW13 using the third write control WC13.

In addition, the control circuit 300 in FIG. 3 may provide the ground voltage VSS to the first reset word-line RWL1 by opening the fourth switch SW14 using the fourth write control WC14 and by closing the fifth switch SW15 using the fifth write control WC15 and may float the first reset bit-line RBL1 by opening the sixth switch SW16 using the sixth write control WC16 and by opening the seventh switch SW17 using the seventh write control WC17. In addition, the row decoder 220 in FIG. 3 may drive the first word-line WL1 and the second word-line WL2 with the ground voltage VSS. Each of the write drivers 420b, 420c, . . . , 420m may drive respective one of the bit-lines BL2, . . . , BLm with the ground voltage VSS. The stand-by state may referred to as a stand-by mode.

Therefore, because a gate-source voltage of each of the selection transistors ST11, ST12, . . . , ST1m is 0[V] and a drain-source voltage of each of the selection transistors ST11, ST12, . . . , ST1m is 0[V], each of the selection transistors ST11, ST12, . . . , ST1m is turned-off. In addition, because a gate-source voltage of the first reset transistor RT1 is 0[V], the first reset transistor RT1 is turned-off.

A voltage applied to the first word-line WL1, a voltage applied to the first bit-line BL1, a voltage applied to the first source line SL1, a voltage applied to the first reset word-line RWL1 and a voltage applied to the first reset bit-line RBL1 in FIG. 12 may be referred to as a bias voltage in the stand-by state.

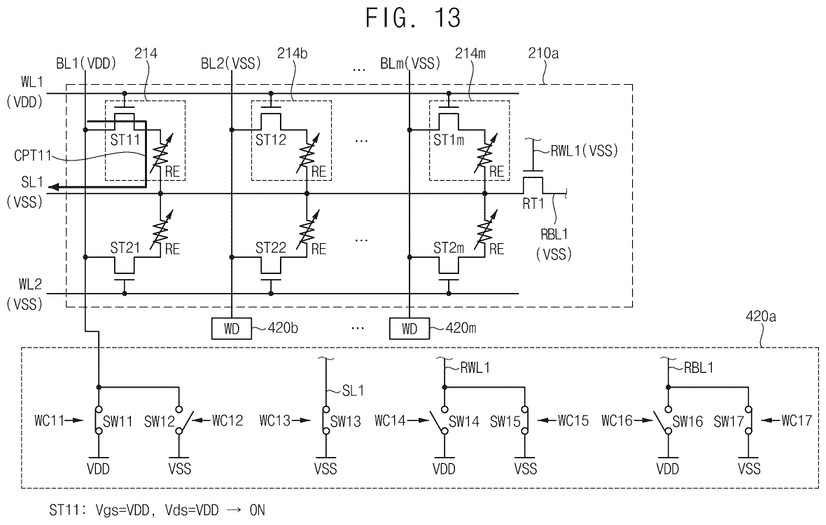

FIG. 13 illustrates resistive memory cell, a first reset transistor and a first write driver in the resistive memory device in FIG. 11 during a set write operation according to example embodiments.

In FIG. 13, descriptions repeated with respect to FIG. 11 will be omitted.

During the set write operation, the control circuit 300 in FIG. 3 may provide the power supply voltage VDD to the first bit-line BL1 by closing the first switch SW11 using the first write control WC11 and by opening the second switch SW12 using the second write control WC12 and may provide the ground voltage VSS to the first source line SL1 by closing the third switch SW13 using the third write control WC13.

In addition, the control circuit 300 in FIG. 3 may provide the ground voltage VSS to the first reset word-line RWL1 by opening the fourth switch SW14 using the fourth write control WC14 and by closing the fifth switch SW15 using the fifth write control WC15 and may provide the ground voltage VSS to the first reset bit-line RBL1 by opening the sixth switch SW16 using the sixth write control WC16 and by closing the seventh switch SW17 using the seventh write control WC17. In addition, the row decoder 220 in FIG. 3 may drive the first word-line WL1 with the power supply voltage VDD and may drive the second word-line WL2 with the ground voltage VSS. Each of the write drivers 420b, 420c, . . . , 420m may drive respective one of the bit-lines BL2, . . . , BLm with the ground voltage VSS.

Therefore, because a gate-source voltage of the selection transistor ST11 is the power supply voltage VDD and a drain-source voltage of the selection transistor ST11 is the power supply voltage VDD, the selection transistor ST11 is turned-on and operates in a saturation region. Accordingly, a current path CPT11 passing through the selection transistor ST11 and the variable resistor element RE is formed (e.g. provided) between the first bit-line BL1 and the first source line SL1, a set current flows through the selection transistor ST11 and the variable resistor element RE and a set write operation is performed on the first resistive memory cell 214 such that the variable resistor element RE has a relatively low resistance. Therefore, the first resistive memory cell 214 may store a bit corresponding to a logic high level.

A voltage applied to the first word-line WL1, a voltage applied to the first bit-line BL1, a voltage applied to the first source line SL1, a voltage applied to the first reset word-line RWL1 and a voltage applied to the first reset bit-line RBL1 in FIG. 13 may be referred to as a set write bias voltage.

In the conventional resistive memory device, a voltage having a voltage level greater than the power supply voltage is applied to the bit-line for performing a set write operation using a transistor that is operating in a linear region. However, according to example embodiments, because the selection transistor ST11 operates in the saturation region instead of the linear region, a set current having sufficient magnitude flows through the selection transistor ST11 and the variable resistor element RE when the power supply voltage VDD is applied to the first bit-line BL1.

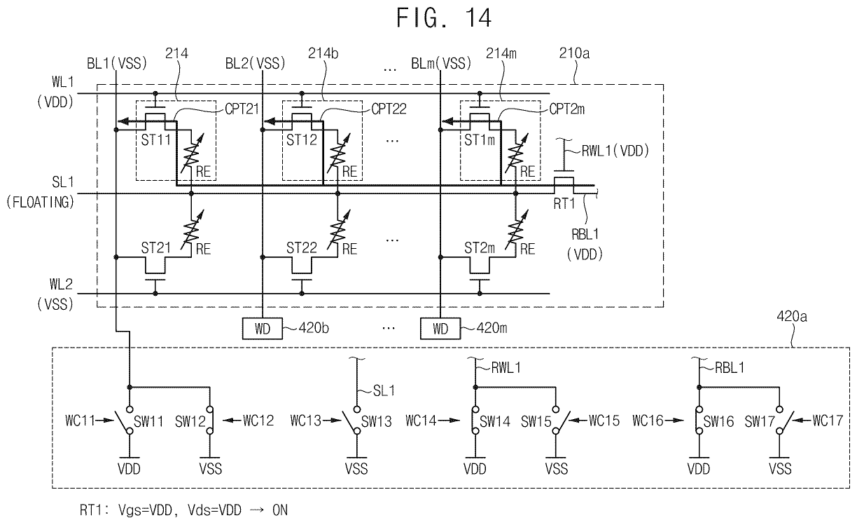

FIG. 14 illustrates resistive memory cell, a first reset transistor and a first write driver in the resistive memory device in FIG. 11 during a reset write operation according to example embodiments.

In FIG. 14, descriptions repeated with respect to FIG. 11 will be omitted.

During the reset write operation, the control circuit 300 in FIG. 3 may provide the ground voltage VSS to the first bit-line BL1 by opening the first switch SW11 using the first write control WC11 and by closing the second switch SW12 using the second write control WC12 and may float the first source line SL1 by opening the third switch SW13 using the third write control WC13.

In addition, the control circuit 300 in FIG. 3 may provide the power supply voltage VDD to the first reset word-line RWL1 by closing the fourth switch SW14 using the fourth write control WC14 and by opening the fifth switch SW15 using the fifth write control WC15 and may provide the power supply voltage VDD to the first reset bit-line RBL1 by closing the sixth switch SW16 using the sixth write control WC16 and by opening the seventh switch SW17 using the seventh write control WC17. In addition, the row decoder 220 in FIG. 3 may drive the first word-line WL1 with the power supply voltage VDD and may drive the second word-line WL2 with the ground voltage VSS. Each of the write drivers 420b, 420c, . . . , 420m may drive respective one of the bit-lines BL2, . . . , BLm with the ground voltage VSS.

Therefore, because a gate-source voltage of the reset transistor RT1 is the power supply voltage VDD and a drain-source voltage of the reset transistor RT1 is the power supply voltage VDD, the reset transistor RT1 is turned-on and operates in a saturation region. Accordingly, a current path CPT21 passing through the variable resistor element RE and the selection transistor ST11 is formed (e.g. provided) between the first source line SL1 and the first bit-line BL1, a reset current flows through variable resistor element RE and the selection transistor ST11 and a reset write operation is performed on the first resistive memory cell 214 such that the variable resistor element RE has a relatively high resistance. Therefore, the first resistive memory cell 214 may store a bit corresponding to a logic low level.

While the current path CPT21 passing through the variable resistor element RE and the selection transistor ST11 is formed between the first source line SL1 and the first bit-line BL1, each of current paths CPT22, . . . , CPT2m passing through the variable resistor element RE and each of the selection transistors ST12, . . . , ST1m may be formed between the first source line SL1 and each of the bit-lines BL2, . . . , BLm.

Therefore, each of the resistive memory cells 214b, . . . , 214m may store a bit corresponding to a logic low level.

A voltage applied to the first word-line WL1, a voltage applied to the first bit-line BL1, a voltage applied to the first source line SL1, a voltage applied to the first reset word-line RWL1 and a voltage applied to the first reset bit-line RBL1 in FIG. 14 may be referred to as a reset write bias voltage.

In the conventional resistive memory device, a voltage having a voltage level greater than the power supply voltage is applied to the bit-line for performing a set write operation using a transistor that is operating in a linear region. However, according to example embodiments, because the first reset transistor RT1 operates in the saturation region instead of the linear region, a reset current having sufficient magnitude flows through the variable resistor element RE and the selection transistor ST11 when the power supply voltage VDD is applied to the first reset bit-line RBL1. Therefore, power consumption may be reduced.

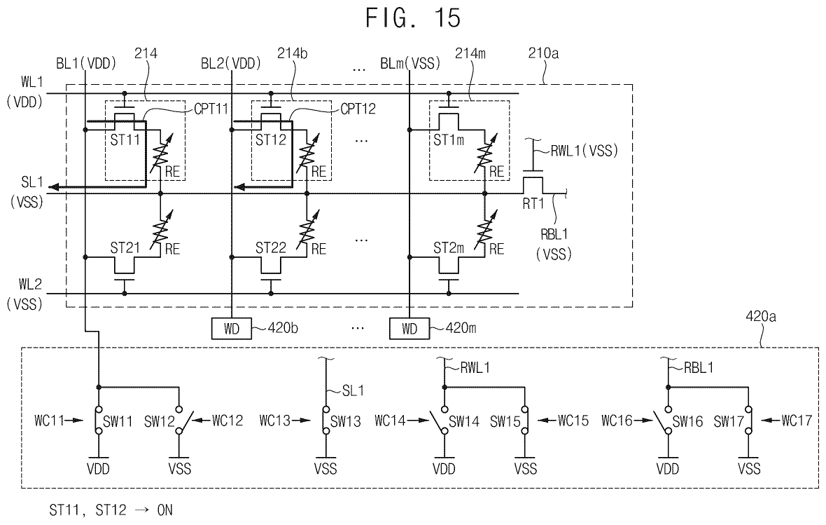

FIG. 15 illustrates resistive memory cell, a first reset transistor and a first write driver in the resistive memory device in FIG. 11 during a set write operation according to example embodiments.

In FIG. 15, descriptions repeated with respect to FIG. 11 will be omitted.

During the set write operation, the control circuit 300 in FIG. 3 may provide the power supply voltage VDD to the first bit-line BL1 by closing the first switch SW11 using the first write control WC11 and by opening the second switch SW12 using the second write control WC12 and may provide the ground voltage VSS to the first source line SL1 by closing the third switch SW13 using the third write control WC13. In addition, the write driver 420b drives the bit-line BL2 with the power supply voltage VDD and the write driver 420m drives the bit-line BLm with the ground voltage VSS under control of the control circuit 300

In addition, the control circuit 300 in FIG. 3 may provide the ground voltage VSS to the first reset word-line RWL1 by opening the fourth switch SW14 using the fourth write control WC14 and by closing the fifth switch SW15 using the fifth write control WC15 and may provide the ground voltage VSS to the first reset bit-line RBL1 by opening the sixth switch SW16 using the sixth write control WC16 and by closing the seventh switch SW17 using the seventh write control WC17. In addition, the row decoder 220 in FIG. 3 may drive the first word-line WL1 with the power supply voltage VDD and may drive the second word-line WL2 with the ground voltage VSS.

Therefore, because a gate-source voltage of each of the selection transistors ST11 and ST12 is the power supply voltage VDD and a drain-source voltage of each of the selection transistors ST11 and ST12 is the power supply voltage VDD, each of the selection transistors ST11 and ST12 is turned-on and operates in a saturation region. Accordingly, a current path CPT11 passing through the selection transistor ST11 and the variable resistor element RE is formed (e.g. provided) between the first bit-line BL1 and the first source line SL1, a set current flows through the selection transistor ST11 and the variable resistor element RE and a set write operation is performed on the first resistive memory cell 214 such that the variable resistor element RE has a relatively low resistance. In addition, a current path CPT12 passing through the selection transistor ST12 and the variable resistor element RE is formed (e.g. provided) between the bit-line BL2 and the first source line SL1, a set current flows through the selection transistor ST12 and the variable resistor element RE and a set write operation is performed on the resistive memory cell 214b such that the variable resistor element RE has a relatively low resistance. Therefore, the resistive memory cell 214b may store a bit corresponding to a logic high level.

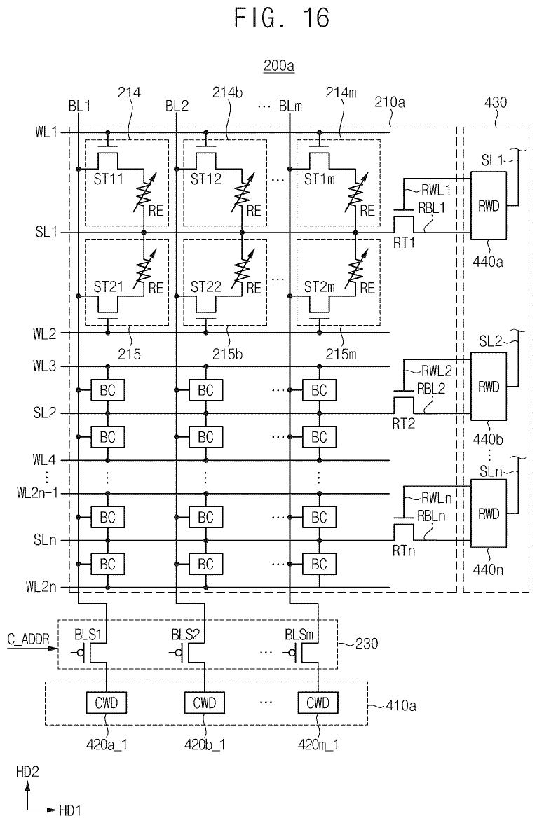

FIG. 16 illustrates a portion of a resistive memory device according to example embodiments.

Referring to FIG. 16, a resistive memory device 200a may include the memory cell array 210a, the column decoder 230 and a first write driver circuit 410a and a second write driver circuit 430.

The first write driver circuit 410a and the second write driver circuit 430 may correspond to the write driver circuit 410 in FIG. 10.

As described with reference to FIG. 4, the memory cell array 210a includes the plurality of word-lines WL1, WL2, WL3, WL4, . . . , WL2n−1 and WL2n extending in the first horizontal direction HD1, the plurality of bit-lines BL1, BL2, . . . , BLm extending in the second horizontal direction HD2, the plurality of source lines SL1, SL2, . . . , SLn extending in the first horizontal direction HD1, the plurality of resistive memory cells and the plurality of reset transistors RT1, RT2, . . . , RTn.

Each of the plurality of source lines SL1, SL2, . . . , SLn may be disposed between two adjacent word-lines among the plurality of word-lines WL1, WL2, WL3, WL4, . . . , WL2n−1 and WL2n. For example, the source line SL1 may be disposed between the word-lines WL1 and WL2, the source line SL2 may be disposed between the word-lines WL3 and WL4 and the source line SLn may be disposed between the word-lines WL2n−1 and WL2n. A row of resistive memory cells coupled to each of the word-lines WL1 and WL2 may be commonly coupled to the source line SL1. Each of the plurality of reset word-lines RWL1, RWL2, . . . , RWLn and each of the plurality of reset bit-lines RBL1, RBL2, . . . , RBLn may be connected to respective one of the plurality of reset transistors RT1, RT2, . . . , RTn.

Each of a first row of resistive memory cells 214, 214b, . . . , 214m may be connected to the first word-line WL1, the first source line SL1 and respective one of the plurality of bit-lines BL1, BL2, . . . , BLm. The first row of resistive memory cells 214, 214b, . . . , 214m may include respective one of selection transistors ST11, ST12, . . . , ST1m and the variable resistor element RE. The variable resistor element RE in each of the first row of resistive memory cells 214, 214b, . . . , 214m may be commonly coupled to the first source line SL1 and may be coupled to the first reset transistor RT1 through the first source line SL1.

Each of a second row of resistive memory cells 215, 215b, . . . , 215m may be connected to the second word-line WL2, the first source line SL1 and respective one of the plurality of bit-lines BL1, BL2, . . . , BLm. The second row of resistive memory cells 215, 215b, . . . , 215m may include respective one of selection transistors ST21, ST22, . . . , ST2m and the variable resistor element RE. The variable resistor element RE in each of the second row of resistive memory cells 215, 215b, . . . , 215m may be commonly coupled to the first source line SL1 and may be coupled to the first reset transistor RT1 through the first source line SL1.

The column decoder 230 may include a plurality of bit-line switches BLS1, BLS2, . . . , BLSm. The first write driver circuit 410a may include a plurality of column write drivers CWD 420a_1, 420b_1, . . . , 420m_1. The second write driver circuit 430 may include a plurality of row write drivers RWD 440a, 440b, . . . , 440n. The column write driver 420a_1 and the row write driver 440a may correspond to the first write driver 420a in FIG. 10.

Each of the plurality of bit-line switches BLS1, BLS2, . . . , BLSm may be connected to respective one of the plurality of bit-lines BL1, BL2, . . . , BLm, and may connect a target column write driver among the plurality of column write drivers 420a_1, 420b_1, . . . , 420m_1 to a target memory cell, based on the column address C_ADDR.

Each of the plurality of column write drivers 420a_1, 420b_1, . . . , 420m_1 may be connected to respective one of the plurality of bit-lines BL1, BL2, . . . , BLm, respective one of the plurality of source lines SL1, SL2, . . . , SLn, respective one of the plurality of reset word-lines RWL1, RWL2, . . . , RWLn and respective one of the plurality of reset bit-lines RBL1, RBL2, . . . , RBLn. Because each of the plurality of source lines SL1, SL2, . . . , SLn may be disposed between two adjacent word-lines among the plurality of word-lines WL1, WL2, WL3, WL4, . . . , WL2n−1 and WL2n, wiring freedom may be increased by connecting each of the plurality of row write drivers 440a, 440b, . . . , 440n to respective one of the plurality of source lines SL1, SL2, . . . , SLn, respective one of the plurality of reset word-lines RWL1, RWL2, . . . , RWLn and respective one of the plurality of reset bit-lines RBL1, RBL2, . . . , RBLn.

During a write operation, corresponding pair of the plurality of column write drivers 420a_1, 420b_1, . . . , 420m_1 and the plurality of row write drivers 440a, 440b, . . . , 440n may drive a bit-line of the target memory cell with one of the power supply voltage VDD and the ground voltage VSS and may drive a source line of the target memory cell with the ground voltage VSS, based on the data DTA, the power supply voltage VDD and the ground voltage VSS.

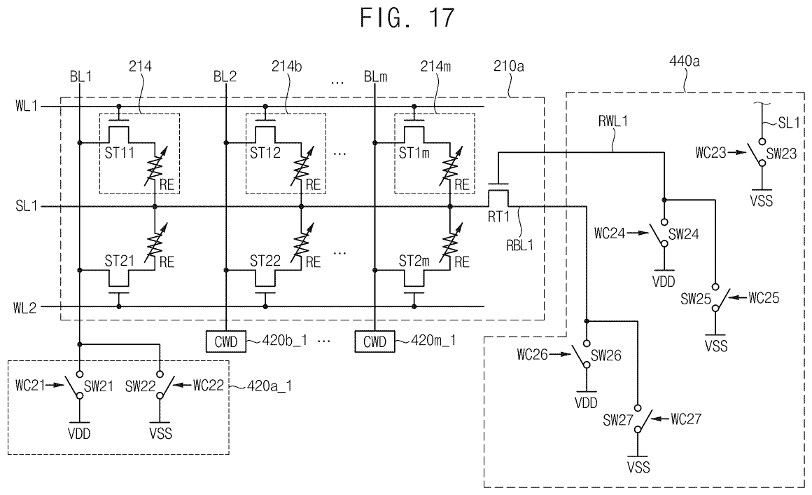

FIG. 17 illustrates an example of a first row of resistive memory cell, a first reset transistor, a first column write driver and a first row write driver in the resistive memory device of FIG. 16 according to example embodiments.

In FIG. 17, the bit-line switch BLS1 is turned-on, the bit-line BL1 is connected to the first write driver 420a_1 and the first word-line WL1 is selected as a target word-line (e.g., a target page). In FIG. 17, a second row of resistive memory cells are illustrated together for convenience of explanation.

The first column write driver 420a_1 may include a first switch SW21 and a second switch SW22, and the first row write driver 440a may include a third switch SW23, a fourth switch SW24, a fifth switch SW25, a sixth switch SW26 and a seventh switch SW27.

The first switch SW21 may selectively provide the power supply voltage VDD to the first bit-line BL1 based on a first write control signal WC21, and the second switch SW22 may selectively provide the ground voltage VSS to the first bit-line BL1 based on a second write control signal WC22.

The third switch SW23 may provide the ground voltage VSS to the first source line SL1 based on a third write control signal WC23.

The fourth switch SW24 may selectively provide the power supply voltage VDD to the first reset word-line RWL1 based on a fourth write control signal WC24, and the fifth switch SW25 may selectively provide the ground voltage VSS to the first reset word-line RWL1 based on a fifth write control signal WC25.

The sixth switch SW26 may selectively provide the power supply voltage VDD to the first reset bit-line RBL1 based on a sixth write control signal WC26, and the seventh switch SW27 may selectively provide the ground voltage VSS to the first reset bit-line RBL1 based on a seventh write control signal WC27.

Although a configuration of the first column write driver 420a_1 and a configuration of the first row write driver 440a are illustrated in FIG. 17, each of the column write drivers 420b_1, . . . , 420m_1 may have a substantially same configuration of the configuration of the first column write driver 420a_1 and a configuration of each of the row write drivers 440b, . . . , 440n may have a substantially same configuration of the configuration of the first row write driver 440a.

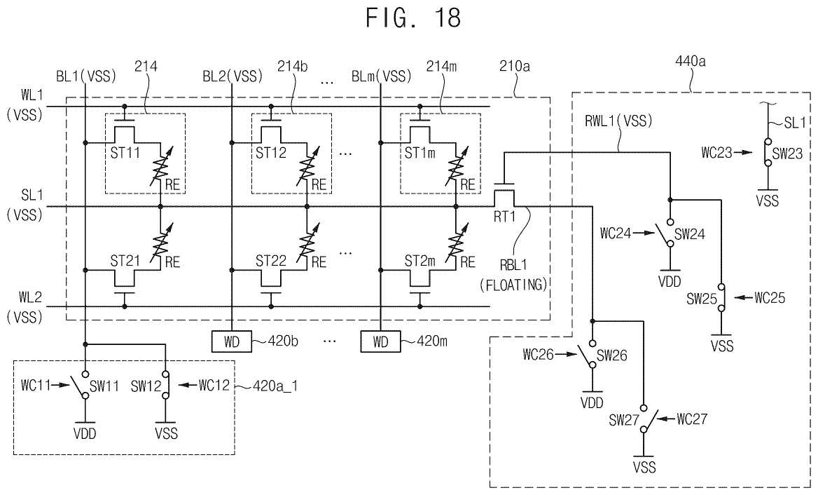

FIG. 18 illustrates resistive memory cell, a first reset transistor, a first column write driver and a first row write driver in the resistive memory device in FIG. 17 in a stand-by state according to example embodiments.

During a stand-by state, the control circuit 300 in FIG. 3 may provide the ground voltage VSS to the first bit-line BL1 by opening the first switch SW21 using the first write control WC21 and by closing the second switch SW22 using the second write control WC12 and may provide the ground voltage VSS to the first source line SL1 by closing the third switch SW23 using the third write control WC23.

In addition, the control circuit 300 in FIG. 3 may provide the ground voltage VSS to the first reset word-line RWL1 by opening the fourth switch SW24 using the fourth write control WC24 and by closing the fifth switch SW25 using the fifth write control WC25 and may float the first reset bit-line RBL1 by opening the sixth switch SW26 using the sixth write control WC26 and by opening the seventh switch SW27 using the seventh write control WC27. In addition, the row decoder 220 in FIG. 3 may drive the first word-line WL1 and the second word-line WL2 with the ground voltage VSS. Each of the column write drivers 420b_1, . . . , 420m_1 may drive respective one of the bit-lines BL2, . . . , BLm with the ground voltage VSS. The stand-by state may referred to as a stand-by mode.

Therefore, because a gate-source voltage of each of the selection transistors ST11, ST12, . . . , ST1m is 0[V] and a drain-source voltage of each of the selection transistors ST11, ST12, . . . , ST1m is 0[V], each of the selection transistors ST11, ST12, . . . , ST1m is turned-off. In addition, because a gate-source voltage of the first reset transistor RT1 is 0[V], the first reset transistor RT1 is turned-off.

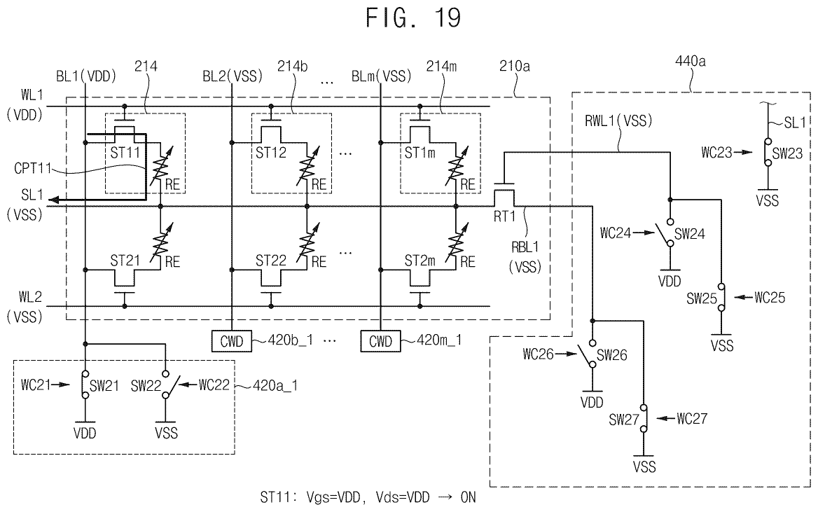

FIG. 19 illustrates resistive memory cell, a first reset transistor, a first column write driver and a first row write driver in the resistive memory device in FIG. 17 during a set write operation according to example embodiments.

In FIG. 19, descriptions repeated with respect to FIG. 17 will be omitted.

During the set write operation, the control circuit 300 in FIG. 3 may provide the power supply voltage VDD to the first bit-line BL1 by closing the first switch SW21 using the first write control WC21 and by opening the second switch SW22 using the second write control WC22 and may provide the ground voltage VSS to the first source line SL1 by closing the third switch SW23 using the third write control WC23.

In addition, the control circuit 300 in FIG. 3 may provide the ground voltage VSS to the first reset word-line RWL1 by opening the fourth switch SW24 using the fourth write control WC24 and by closing the fifth switch SW25 using the fifth write control WC25 and may provide the ground voltage VSS to the first reset bit-line RBL1 by opening the sixth switch SW26 using the sixth write control WC26 and by closing the seventh switch SW27 using the seventh write control WC27. In addition, the row decoder 220 in FIG. 3 may drive the first word-line WL1 with the power supply voltage VDD and may drive the second word-line WL2 with the ground voltage VSS. Each of the column write drivers 420b_1, . . . , 420m_1 may drive respective one of the bit-lines BL2, . . . , BLm with the ground voltage VSS.

Therefore, because a gate-source voltage of the selection transistor ST11 is the power supply voltage VDD and a drain-source voltage of the selection transistor ST11 is the power supply voltage VDD, the selection transistor ST11 is turned-on and operates in a saturation region. Accordingly, a current path CPT11 passing through the selection transistor ST11 and the variable resistor element RE is formed (e.g. provided) between the first bit-line BL1 and the first source line SL1, a set current flows through the selection transistor ST11 and the variable resistor element RE and a set write operation is performed on the first resistive memory cell 214 such that the variable resistor element RE has a relatively low resistance. Therefore, the first resistive memory cell 214 may store a bit corresponding to a logic high level.

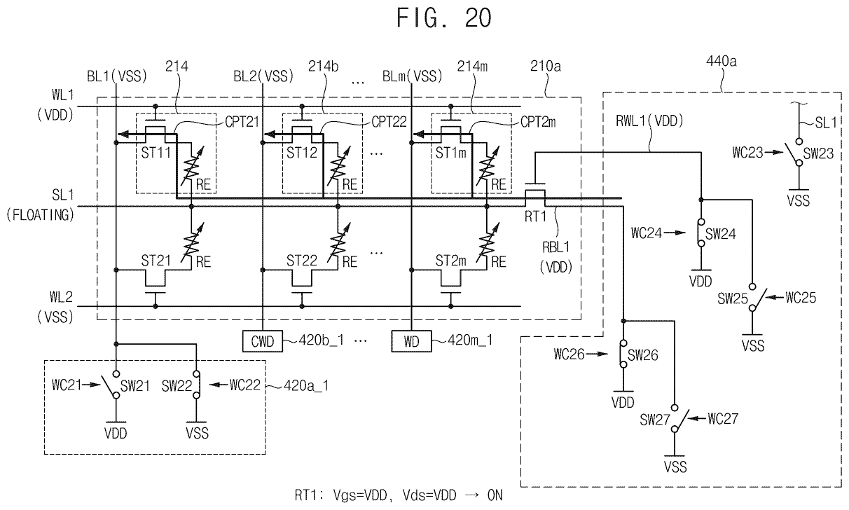

FIG. 20 illustrates resistive memory cell, a first reset transistor, a first column write driver and a first row write driver in the resistive memory device in FIG. 17 during a reset write operation according to example embodiments.

In FIG. 20, descriptions repeated with respect to FIG. 17 will be omitted.

During the reset write operation, the control circuit 300 in FIG. 3 may provide the ground voltage VSS to the first bit-line BL1 by opening the first switch SW21 using the first write control WC21 and by closing the second switch SW22 using the second write control WC22 and may float the first source line SL1 by opening the third switch SW23 using the third write control WC23.

In addition, the control circuit 300 in FIG. 3 may provide the power supply voltage VDD to the first reset word-line RWL1 by closing the fourth switch SW24 using the fourth write control WC24 and by opening the fifth switch SW25 using the fifth write control WC25 and may provide the power supply voltage VDD to the first reset bit-line RBL1 by closing the sixth switch SW26 using the sixth write control WC26 and by opening the seventh switch SW27 using the seventh write control WC27. In addition, the row decoder 220 in FIG. 3 may drive the first word-line WL1 with the power supply voltage VDD and may drive the second word-line WL2 with the ground voltage VSS. Each of the column write drivers 420b_1, . . . , 420m_1 may drive respective one of the bit-lines BL2, . . . , BLm with the ground voltage VSS.

Therefore, because a gate-source voltage of the reset transistor RT1 is the power supply voltage VDD and a drain-source voltage of the reset transistor RT1 is the power supply voltage VDD, the reset transistor RT1 is turned-on and operates in a saturation region. Accordingly, a current path CPT21 passing through the variable resistor element RE and the selection transistor ST11 is formed (e.g. provided) between the first source line SL1 and the first bit-line BL1, a reset current flows through variable resistor element RE and the selection transistor ST11 and a reset write operation is performed on the first resistive memory cell 214 such that the variable resistor element RE has a relatively high resistance. Therefore, the first resistive memory cell 214 may store a bit corresponding to a logic low level.

While the current path CPT21 passing through the variable resistor element RE and the selection transistor ST11 is formed between the first source line SL1 and the first bit-line BL1, each of current paths CPT22, . . . , CPT2m passing through the variable resistor element RE and each of the selection transistors ST12, . . . , ST1m may be formed between the first source line SL1 and each of the bit-lines BL2, . . . , BLm.

Therefore, each of the resistive memory cells 214b, . . . , 214m may store a bit corresponding to a logic low level.

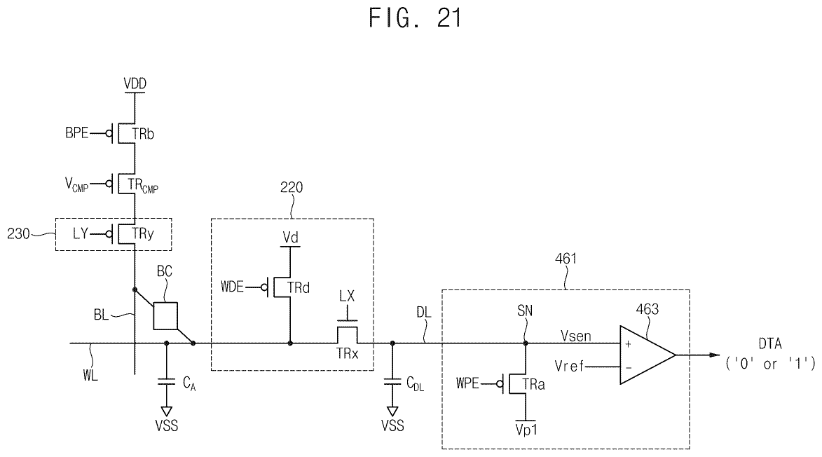

FIG. 21 illustrates a circuit diagram illustrating components associated with performing a read operation of a resistive memory device according to example embodiments.

Referring to FIG. 21, a word-line WL may be connected to one end of a resistive memory cell BC, and a bit-line BL may be connected to the other end of the resistive memory cell BC. The row decoder 220 may be connected to the word-line WL. For example, the row decoder 220 may include a word-line selection transistor TRx and a discharge transistor TRd. The word-line selection transistor TRx may be turned on or off in response to a word line selection signal LX. When the word-line selection transistor TRx is turned on, the word-line WL may be connected to a sense amplifier 461 through a data line DL. The discharge transistor TRd may be turned on or off in response to a discharge enable signal WDE. When the discharge transistor TRd is turned on, a discharge voltage Vd may be applied to the word line WL. For example, the discharge voltage Vd may be the ground voltage VSS.

The column decoder 230 may be connected to the bit-line BL and may include a bit-line selection transistor TRy. Also, the column decoder 230 may further include a discharge transistor (not shown). The bit-line selection transistor TRy may be connected to control switches, for example, a clamping transistor TR_{CMP} and a bit-line precharge transistor TRb. The bit-line precharge transistor TRb and the clamping transistor TR_{CMP} may be understood as components of the sense amplifier 461. The bit-line selection transistor TRy is turned on or off in response to a bit-line selection signal LY. The bit-line precharge transistor TRb may be turned on or off in response to a bit-line precharge enable signal BPE. In this case, the clamping transistor TR_{CMP} may be controlled to apply a certain voltage to the bit-line BL based on a clamping voltage V_{CMP}.

The sense amplifier 461 may include a word-line precharge transistor TRa and a comparator 463. The word-line precharge transistor TRa may be turned on or off in response to a word-line precharge enable signal WPE. When the word line selection transistor TRx and the word-line precharge transistor TRa are turned-on, a first pre-charge voltage Vp1 may be applied to the word-line WL. The word-line WL and the bit-line BL may each include a parasitic capacitor, and the capacitance of the parasitic capacitor of the word-line WL, for example, a word-line capacitor C_{A}, may be less than that of the parasitic capacitor (not shown) of the bit-line BL. Accordingly, the comparator 463 may be connected to the word-line WL having relatively little influence by the parasitic capacitor and may sense the voltage level of the word-line WL, thereby reading data of a selected resistive memory cell BC. The data line DL may include a parasitic capacitor, and the capacitance of the parasitic capacitor of the data line DL, for example, may be a data line capacitor C_{DL}.

The comparator 463 may compare a sensing voltage Vsen of a sensing node SN, for example a voltage level of the data line DL (in this case, the voltage level of the data line DL is the same as the voltage level of the word-line WL), with a reference voltage Vref, and may output a comparison result as data DTA. For example, when the resistive memory cell BC is in a set state, the sensing voltage Vsen may be higher than the reference voltage Vref, and the comparator 463 may output ‘1’ as the data DTA. When the resistive memory cell BC is in a reset state, the sensing voltage Vsen may be lower than the reference voltage Vref, and the comparator 463 may output ‘0’ as the data DTA.

The resistive memory cell BC may employ the resistive memory cell 214 of FIG. 5.

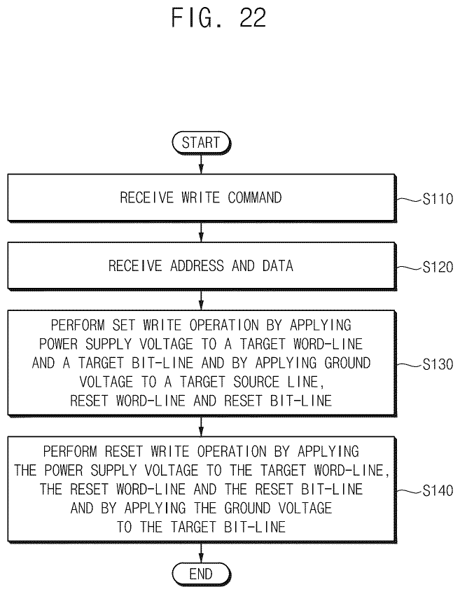

FIG. 22 is a flow chart illustrating a method of operating a resistive memory device according to example embodiments.

In FIG. 22, the resistive memory cell 214 in FIG. 3 includes the resistive memory cell 214 of FIG. 5, and the memory cell array 210 employs the memory cell array 210a in FIG. 10.

Referring to FIGS. 1, 3 through 5, 7A through 15 and 22, the resistive memory device 200 receives a write command from an external memory controller 100 (operation S110). The resistive memory device 200 includes the memory cell array 210a, and the memory cell array 210a includes a plurality of resistive memory cells and a plurality of reset transistors coupled to a plurality of source lines, respectively. Each of the plurality of source lines is disposed between two adjacent word-lines among the plurality of word-lines. The resistive memory device 200 receives a data DTA and an address ADDR from the external memory controller 100 (operation S120).

The control circuit 300 performs a set write operation on a target page (operation S130) by applying the power supply voltage VDD to a first word-line WL1, by applying the ground voltage VSS to a second word-line WL2, by applying the power supply voltage VDD to a first bit-line BL1 and by applying the ground voltage VSS to a first source lines SL1.

The control circuit 300 performs a reset write operation on the target page (operation S140) by applying the power supply voltage VDD to a first word-line WL1, by applying the ground voltage VSS to the second word-line WL2, by applying the ground voltage VSS to the first bit-line BL1 and by applying the power supply voltage VDD to a first reset bit-line RBL1 coupled to a drain of a first reset transistor RT1.

When the reset write operation is performed on the first resistive memory cell 214, the first reset transistor RT1 operating in a saturation region may be used.

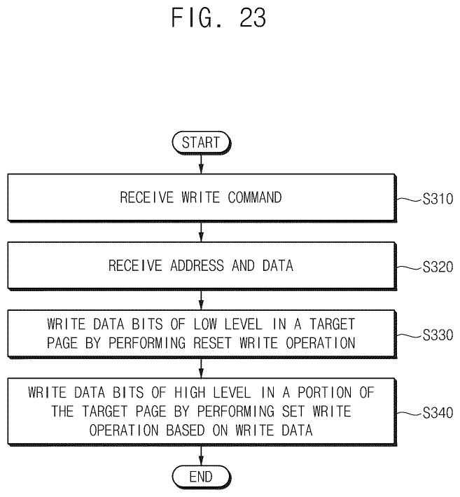

FIG. 23 is a flow chart illustrating a method of operating a resistive memory device according to example embodiments.

In FIG. 23, the resistive memory cell 214 in FIG. 3 includes the resistive memory cell 214 of FIG. 5, and the memory cell array 210 employs the memory cell array 210a in FIG. 10.

Referring to FIGS. 1, 3 through 5, 7A through 15 and 23, the resistive memory device 200 receives a write command from an external memory controller 100 (operation S310). The resistive memory device 200 includes the memory cell array 210a, and the memory cell array 210a includes a plurality of resistive memory cells and a plurality of reset transistors coupled to a plurality of source lines, respectively. Each of the plurality of source lines is disposed between two adjacent word-lines among the plurality of word-lines. The resistive memory device 200 receives a data DTA and an address ADDR from the external memory controller 100 (operation S320).

The control circuit 300 performs a reset write operation on a target page (operation S330) by applying the power supply voltage VDD to a first word-line among the plurality of word-lines, by applying the ground voltage VSS to a plurality of bit-lines BL1, BL2, . . . , BLm and by applying the power supply voltage VDD to a first reset word-line RWL1 and a first reset bit-line RBL1 of a first reset transistor RT1 among the plurality of reset transistors RT1, RT2, . . . , RTn. Each of resistive memory cells of the target page includes a variable resistor element RE and a respective selection transistor, the variable resistor element RE is coupled to a first source line SL1 among the plurality of source lines, each of the selection transistors is coupled to the first word-line WL1 and each of the plurality of bit-lines BL1, BL2, . . . , BLm coupled to the column decoder 230 and a write driver circuit 420, the first reset word-line RWL1 is coupled to a gate of the first reset transistor RT1 coupled to the first source line SL1 and the first reset bit-line RBL1 is coupled to a drain of the first reset transistor RT1.

The control circuit 300 performs a set write operation on a portion of the target page corresponding to bits having a logic high level, among the data (operation S340) by applying the power supply voltage VDD to the first word-line WL1, by applying the power supply voltage VDD to a portion or subset of the plurality of bit-lines BL1, BL2, . . . , BLm based on the data and by applying the ground voltage VSS to the first source line SL1.

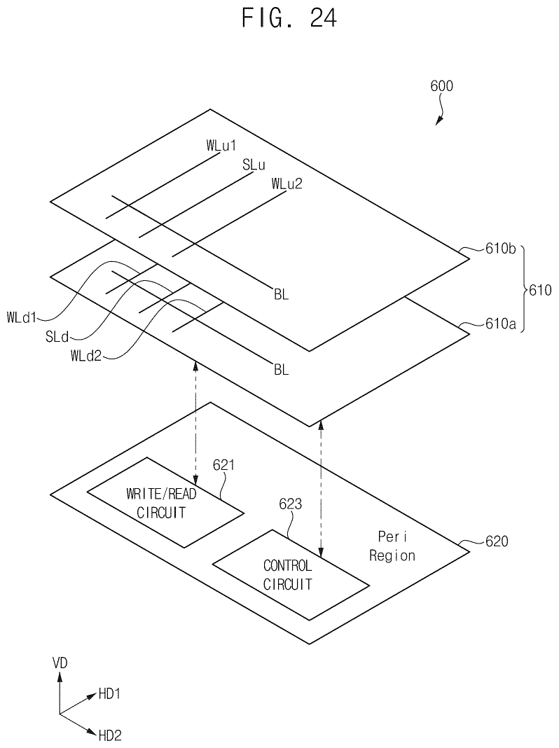

FIG. 24 illustrates a memory device having a cell over peripheral (COP) structure according to example embodiments.

Referring to FIG. 24, a memory device 600 may include first and second semiconductor layers 610 and 620 stacked in a vertical direction VD. The first semiconductor layer 610 may include first and second layers 610a and 610b. In some embodiments, the first semiconductor layer 610 may further include at least one layer on the second layer 610b. The first layer 610a may include lower word-lines WLd1 and WLd2 and a source line SLd shared by the lower word-lines WLd1 and WLd2, the second layer 610b may include upper word-lines WLu1 and WLu2 and a source line SLu shared by the upper word-lines WLu1 and WLu2, and the first layer 610a and the second layer 610b may share bit-lines BL. The source line SLd may be disposed between the lower word-lines WLd1 and WLd2 and the source line SLu may be disposed between the upper word-lines WLu1 and WLu2.

The lower word-lines WLd1 and WLd2 and the source line SLd may extend in the first horizontal direction HD1 and the bit-lines BL may extend in the second horizontal direction HD2 crossing or intersecting the first horizontal direction HD1. The upper word-lines WLu1 and WLu2 and the source line SLu may extend in the first horizontal direction HD1.

The first layer 610a may further include lower memory cells respectively arranged in regions where the lower word-lines WLd1 and WLd2 and the source line SLd intersect with the bit-lines BL and lower reset transistors, and the second layer 610b may further include upper memory cells respectively arranged in regions where the upper word-lines WLu1 and WLu2 and the source line SLu intersect with the bit-lines BL and upper reset transistors.

A peripheral circuit region Peri Region including peripheral circuits may be arranged on the second semiconductor layer 620. For example, a write/read circuit 621 and a control circuit 623 may be arranged on the second semiconductor layer 620. However, the present disclosure is not limited thereto, and various types of peripheral circuits related to memory operations may be arranged in the second semiconductor layer 620.

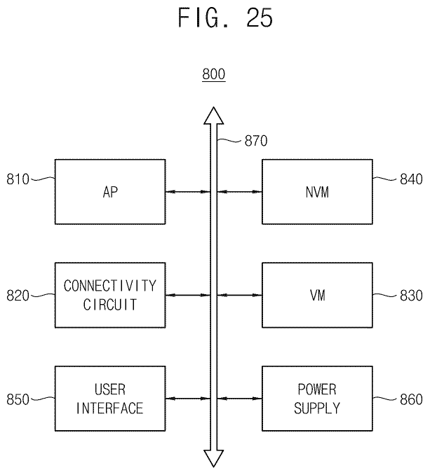

FIG. 25 is a block diagram illustrating a mobile system according to some example embodiments.

Referring to FIG. 25, a mobile system 800 includes an application processor (AP) 810, a connectivity circuit 820 a volatile memory device VM 830, a nonvolatile memory device NVM 840, a user interface 850, and a power supply 860 connected through a system bus 870. Any or all of the components of the mobile system 800, such as the AP 810, the connectivity circuit 820, the volatile memory device 830, the nonvolatile memory device 840, the user interface 850, or the power supply 860 may include processing circuitry such as hardware including logic circuits; a hardware/software combination such as a processor executing software; or a combination thereof.

The application processor 810 may execute applications such as at least one of a web browser, a game application, a video player, etc. The connectivity circuit 820 may perform wired and/or wireless communication with an external device.

The volatile memory device 830 may store data processed by the application processor 3100, or may operate as a working memory. For example, the volatile memory device 830 may be or include a DRAM, such as at least one of a double data rate synchronous dynamic random access memory (DDR SDRAM), low power DDR (LPDDR) SDRAM, graphics DDR (GDDR) SDRAM, Rambus DRAM (RDRAM), etc.

The nonvolatile memory device 840 may store a boot image for booting the mobile system 800 and other data. The nonvolatile memory device 840 may be or include a phase change random access memory (PRAM) using a phase change materials, a resistance random access memory (RRAM) using a variable resistance material such as complex metal oxide, and/or a magneto-resistive random access memory (MRAM) using a magnetic material. The nonvolatile memory device 840 may employ the resistive memory device 200 of FIG. 3.

The user interface 850 may include at least one input device, such as a keypad, a touch screen, etc., and at least one output device, such as a speaker, a display device, etc. The power supply 860 may supply a power supply voltage to the mobile system 800.

As described with reference to FIGS. 3 through 20, the nonvolatile memory device 840 may include a plurality of resistive memory cells coupled to a plurality of word-lines and a plurality of reset transistors, each of the plurality of resistive memory cells includes a variable resistor element coupled to respective one of a plurality of source lines, each of the plurality of source lines is connected to respective one of the reset transistors and each of the plurality of source lines is shared by two adjacent word-lines. The nonvolatile memory device 840 performs a set write operation using a selection transistor in the resistive memory cell and performs a reset write operation using the reset transistor that operates in a saturation region. Because resistive memory cells coupled to the two adjacent word-lines commonly use (i.e., are commonly coupled to or share) one reset transistor, occupied area may be reduced. In addition, because each of the selection transistor and the reset transistor operates in the saturation region, a set current having sufficient magnitude is generated when the power supply voltage is applied to the bit-line. Accordingly, the nonvolatile memory device 840 may reduce power consumption and enhance performance by increasing uniformity characteristics of the resistive memory cells.

The example embodiments of present disclosure may be applied to resistive memory devices and systems including the resistive memory devices.

The example embodiments of the present disclosure may be applied to various electronic devices and systems that include the self-selecting memories. For example, the inventive concepts may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automobile, etc.

While the present disclosure has been shown and described with reference to example embodiments thereof, it will be apparent to those of ordinary skill in the art that many modifications in form and details may be made thereto without materially departing from the scope of the present disclosure as set forth by the following claims.

What is claimed is:

1. A resistive memory device comprising:
a memory cell array comprising a plurality of resistive memory cells and a plurality of reset transistors, the plurality of resistive memory cells coupled to a plurality of word-lines, each of the plurality of reset transistors coupled to a respective one of a plurality of source lines that is between a respective pair of adjacent word-lines among the plurality of word-lines; and
a write/read circuit connected to the memory cell array through a row decoder and through a column decoder, the write/read circuit configured to write a write data in a target page of the memory cell array,
wherein a first resistive memory cell of the target page among the plurality of resistive memory cells comprises:
a variable resistor element coupled to a first source line among the plurality of source lines; and
a first selection transistor coupled to a first bit-line, the variable resistor element, and a first word-line among the plurality of word-lines,
wherein the first bit-line is coupled to the column decoder and a first write driver of the write/read circuit,
wherein a first reset transistor among the plurality of reset transistors is connected to the first source line, a reset word-line, and a reset bit-line, and
wherein the first write driver is configured to perform a set write operation using the first selection transistor and perform a reset write operation using the first reset transistor.

2. The resistive memory device of claim 1, wherein the first selection transistor comprises a first n-channel metal-oxide semiconductor (NMOS) transistor that has a drain coupled to the first bit-line, a gate coupled to the first word-line, and a source coupled to the variable resistor element, and
wherein the first reset transistor comprises a second NMOS transistor that has a drain coupled to the reset bit-line, a gate coupled to the reset word-line, and a source coupled to the first source line.

3. The resistive memory device of claim 1, wherein, during a stand-by state,
the row decoder is configured to turn-off the first selection transistor by applying a ground voltage to the first word-line, and
the first write driver is configured to turn-off the first reset transistor by applying the ground voltage to the first bit-line and the reset word-line.

4. The resistive memory device of claim 1, wherein, during the set write operation,
the row decoder is configured to turn-on the first selection transistor by applying a power supply voltage to the first word-line and apply a ground voltage to a second word-line among the plurality of word-lines that is adjacent to the first source line, and
the first write driver is configured to provide a current path passing through the first selection transistor and the variable resistor element, between the first bit-line and the first source line, by applying the power supply voltage to the first bit-line and by applying a ground voltage to the first source line, the reset word-line and the reset bit-line.

5. The resistive memory device of claim 4, wherein, during the set write operation, the first selection transistor is configured to operate in a saturation region.

6. The resistive memory device of claim 1, wherein, during the reset write operation,
the row decoder is configured to turn-on the first selection transistor by applying a power supply voltage to the first word-line and applying a ground voltage to a second word-line among the plurality of word-lines that is adjacent to the first source line, and
the first write driver is configured to provide a current path passing through the variable resistor element and the first selection transistor, between the first source line and the first bit-line, by applying the ground voltage to the first bit-line and by applying the power supply voltage to the reset word-line and the reset bit-line.

7. The resistive memory device of claim 6, wherein, during the reset write operation, the first reset transistor is configured to operate in a saturation region.

8. The resistive memory device of claim 6, wherein the write/read circuit is configured to perform the reset write operation on a first row of the resistive memory cells coupled to the first word-line and including the first resistive memory cell in parallel with other resistive memory cells thereof.

9. The resistive memory device of claim 1, wherein the first write driver comprises:
a first switch configured to selectively provide a power supply voltage to the first bit-line responsive to a first write control signal;
a second switch configured to selectively provide a ground voltage to the first bit-line responsive to a second write control signal;
a third switch configured to provide the ground voltage to the first source line responsive to a third write control signal;
a fourth switch configured to selectively provide the power supply voltage to the reset word-line responsive to a fourth write control signal;
a fifth switch configured to selectively provide the ground voltage to the reset word-line responsive to a fifth write control signal;
a sixth switch configured to selectively provide the power supply voltage to the reset bit-line responsive to a sixth write control signal; and
a seventh switch configured to selectively provide the ground voltage to the reset bit-line responsive to a seventh write control signal.

10. The resistive memory device of claim 9, wherein, during the set write operation,
the row decoder is configured to turn-on the first selection transistor by applying the power supply voltage to the first word-line and applying the ground voltage to a second word-line among the plurality of word-lines that is adjacent to the first source line,
the first switch is closed and the second switch is open to provide the power supply voltage to the first bit-line,
the third switch is closed to provide the ground voltage to the first source line,
the fourth switch is open and the fifth switch is closed to provide the ground voltage to the reset word-line, and
the sixth switch is open and the seventh switch is closed to provide the ground voltage to the reset bit-line.

11. The resistive memory device of claim 9, wherein, during the reset write operation,
the row decoder is configured to turn-on the first selection transistor by applying the power supply voltage to the first word-line and apply the ground voltage to a second word-line among the plurality of word-lines that is adjacent to the first source line,
the first switch is open and the second switch is closed to provide the ground voltage to the first bit-line,
the third switch is open to float the first source line,
the fourth switch is closed and the fifth switch is open to provide the power supply voltage to the reset word-line, and
the sixth switch is closed and the seventh switch is open to provide the power supply voltage to the reset bit-line.

12. The resistive memory device of claim 1, wherein the first write driver comprises:
a first column write driver connected to the first bit-line and configured to drive the first bit-line with a power supply voltage and a ground voltage; and
a first row write driver connected to the first source line, the reset word-line and the reset bit-line.

13. The resistive memory device of claim 12, wherein, during the set write operation,
the row decoder is configured to turn-on the first selection transistor and turn-off a second selection transistor by applying a power supply voltage to the first word-line, and
the first column write driver and the first row write driver are configured to provide a current path passing through the first selection transistor and the variable resistor element, between the first bit-line and the first source line, by operating the first column write driver to apply the power supply voltage to the first bit-line and by operating the first row write driver to apply the ground voltage to the first source line, the reset word-line and the reset bit-line, and
wherein the first selection transistor is configured to operate in a saturation region.

14. The resistive memory device of claim 12, wherein, during the reset write operation,
the row decoder is configured to turn-on the first selection transistor by applying a power supply voltage to the first word-line and applying a ground voltage a second word-line among the plurality of word-lines that is adjacent to the first source line, and
the first column write driver and the first row write driver are configured to provide a current path passing through the variable resistor element and the first selection transistor, between the first source line and the first bit-line, by operating first column write driver to apply the ground voltage to the first bit-line and by operating the first row write driver to apply the power supply voltage to the reset word-line and the reset bit-line, and
wherein the first selection transistor is configured to operate in a saturation region.

15. The resistive memory device of claim 1, wherein, in a write operation on the target page, a reset write operation is configured to be performed on resistive memory cells in the target page by:
operating the row decoder to apply a power supply voltage to the first word-line and to apply a ground voltage to a second word-line among the plurality of word-lines that is adjacent to the first source line; and
operating the write/read circuit to apply the power supply voltage to bit-lines coupled to the target page, to apply the power supply voltage to the reset word-line and the reset bit-line, and to float the first source line, and
a set write operation is configured to be performed on resistive memory cells corresponding to bits having a logic high level, among the write data, by:
operating the row decoder to apply the power supply voltage to the first word-line and to apply a ground voltage a second word-line adjacent to the first source line; and
operating the write/read circuit to apply the power supply voltage to a subset of the bit-lines coupled to the target page and to apply the ground voltage to the first source line.

16. The resistive memory device of claim 1, further comprising:
a control circuit configured to control the row decoder, the column decoder and the write/read circuit based on a command and an address, wherein the control circuit comprises:
a command decoder configured to generate a decoded command by decoding the command received from an external memory controller;
an address buffer configured to generate a row address and a column address based on the address received from the external memory controller, provide the row address to the row decoder, and provide the column address to the column decoder; and
a control signal generator configured to generate control signals for controlling the row decoder, the column decoder, and the write/read circuit based on the decoded command.

17. The resistive memory device of claim 1, further comprising:
a first layer and a second layer sharing a plurality of bit-lines, the first layer and the second layer being stacked; and
a peripheral circuit region under the first layer,
wherein each of the first layer and the second layer comprises the plurality of resistive memory cells at intersections of the plurality of word-lines, the plurality of bit-lines, and the plurality of source lines, each of the plurality of source lines being between the respective pair of adjacent word-lines among the plurality of word-lines and
wherein a control circuit and the write/read circuit are in the peripheral circuit region.

18. A method of operating a resistive memory device including a memory cell array that comprises a plurality of resistive memory cells and a plurality of reset transistors, the plurality of resistive memory cells coupled to a plurality of word-lines, each of the plurality of reset transistors coupled to respective one of a plurality of source lines that is between a respective pair of adjacent word-lines among the plurality of word-lines, the method comprising:
receiving a write command from an external memory controller;
receiving an address and a data from the external memory controller;
performing a reset write operation on a target page of the memory cell array by applying a power supply voltage to a first word-line among the plurality of word-lines, by applying a ground voltage to a plurality of bit-lines, and by applying the power supply voltage to a first reset word-line and a first reset bit-line that are coupled to a gate and a drain, respectively, of a first reset transistor among the plurality of reset transistors,
wherein each of the resistive memory cells of the target page comprises a variable resistor element that is coupled to a first source line among the plurality of source lines, and a selection transistor that is coupled to the first word-line and a first bit line among a plurality of bit-lines coupled to a column decoder and a write driver circuit, wherein the first reset transistor is coupled to the first source line; and
performing a set write operation on a portion of the target page corresponding to bits having a logic high level, among the data, by applying the power supply voltage to the first word-line, by applying the power supply voltage to a subset of the plurality of bit-lines based on the data, and by applying the ground voltage to the first source line.

19. The method of claim 18, wherein the first reset transistor is configured to operate in a saturation region during the reset write operation, and
wherein a first selection transistor that is coupled to the first word-line and a first bit-line of the subset is configured to operate in a saturation region during the set write operation.

20. A resistive memory device comprising:
a memory cell array comprising a plurality of resistive memory cells and a plurality of reset transistors, the plurality of resistive memory cells coupled to a plurality of word-lines, each of the plurality of reset transistors coupled to respective one of a plurality of source lines that is between a respective pair of adjacent word-lines among the plurality of word-lines;
a write/read circuit connected to the memory cell array through a row decoder and through a column decoder, the write/read circuit configured to write a write data in a target page of the memory cell array; and
a control circuit configured to control the row decoder, the column decoder, and the write/read circuit based on a command and an address,
wherein a first resistive memory cell of the target page among the plurality of resistive memory cells comprises:
a variable resistor element coupled to a first source line among the plurality of source lines; and
a first selection transistor coupled to a first bit-line, the variable resistor element, and a first word-line among the plurality of word-lines,
wherein the first bit-line is coupled to the column decoder and a first write driver of the write/read circuit, and
wherein a first reset transistor among the plurality of reset transistors is connected to the first source line, a reset word-line, and a reset bit-line,
wherein the first write driver is configured to perform a set write operation using the first selection transistor and perform a reset write operation using the first reset transistor,
wherein the first selection transistor and the first reset transistor are configured to operate in a saturation region during the set write operation and the reset write operation, respectively.
